(19) United States
(12) Patent Application Publication
(10) Pub. No.: US 2023/0282681 A1
(43) Pub. Date: Sep. 7, 2023

(54) DISPLAY DEVICE AND METHOD OF FABRICATING THE SAME

(71) Applicant: Samsung Display Co., LTD., Yongin-si (KR)

(72) Inventors: Jae Hee KIM, Yongin-si (KR); Ki Nyeng KANG, Yongin-si (KR); In Pyo KIM, Yongin-si (KR); Jeong Kook WANG, Yongin-si (KR); Hyo Jeong LEE, Yongin-si (KR); Jong Hwan CHA, Yongin-si (KR)

(73) Assignee: Samsung Display Co., LTD., Yongin-si (KR)

(21) Appl. No.: 18/109,961

(22) Filed: Feb. 15, 2023

(30) Foreign Application Priority Data
Mar. 3, 2022 (KR) 10-2022-0027526

(51) Int. Cl. H01L 27/15; H01L 33/24; H01L 33/44; H01L 33/00

(52) U.S. Cl. CPC H01L 27/156; H01L 33/24; H01L 33/44; H01L 33/005

(57) ABSTRACT

A display device includes electrodes disposed in a display area and spaced apart from each other, light emitting elements disposed between the electrodes, conductive lines disposed in a non-display area and electrically connected to the electrodes, and dummy pixels disposed on the conductive lines. The dummy pixels each may include dummy partition walls spaced apart from each other, and dummy electrodes disposed on the partition walls and spaced apart from each other.

### CROSS-REFERENCE TO RELATED APPLICATION(S)

This application claims priority to and benefits of Korean patent application number 10-2022-0027526 under 35 U.S.C. § 119 filed on Mar. 3, 2022 in the Korean Intellectual Property Office, the entire contents of which are incorporated herein by reference.

### BACKGROUND

### 1. Technical Field

Embodiments relate to a display device and a method of fabricating the display device.

### 2. Description of the Related Art

Recently, as interest in information display increases, research and development on display devices have been continuously conducted.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Various embodiments are directed to a display device capable of minimizing a spot defect, and a method of fabricating the display device.

Objects of the disclosure are not limited to the above-stated objects, and those skilled in the art will clearly understand other objects from the accompanying claims.

A display device in accordance with an embodiment may include electrodes disposed in a display area and spaced apart from each other; light emitting elements disposed between the electrodes; conductive lines disposed in a non-display area and electrically connected to the electrodes; and dummy pixels disposed on the conductive lines. The dummy pixels each may include dummy partition walls spaced apart from each other; and dummy electrodes disposed on the partition walls and spaced apart from each other.

The electrodes and the dummy electrodes may be disposed on a same layer.

The electrodes may include a first electrode adjacent to first ends of the light emitting elements, and a second electrode adjacent to second ends of the light emitting elements.

The conductive lines may comprise a first conductive line electrically connected to the first electrode, and a second conductive line electrically connected to the second electrode.

The display device may further include partition walls overlapping the electrodes in a plan view.

The partition walls and the dummy partition walls may be disposed on a same layer.

A method of fabricating a display device in accordance with an embodiment may include forming alignment lines on a substrate; forming dummy electrodes on the alignment lines; forming electrodes connected with the alignment lines, providing light emitting elements on the substrate; and aligning the light emitting elements between the electrodes by applying alignment voltages to the alignment lines.

The electrodes and the dummy electrodes may be simultaneously formed.

The method may further include forming dummy partition walls between the alignment lines and the dummy electrodes.

The method may further include forming partition walls overlapping the electrodes in a plan view.

The partition walls and the dummy partition walls may be simultaneously formed.

The alignment lines may be formed in a cutting area of the substrate.

The dummy electrodes may be formed in the cutting area of the substrate.

The electrodes may be formed in a panel area of the substrate.

The method may further include forming conductive lines in the panel area of the substrate, the conductive lines connecting the alignment lines and the electrodes to each other.

The method may further include forming a display panel by cutting the cutting area of the substrate.

The electrodes may include a first electrode adjacent to first ends of the light emitting elements, and a second electrode adjacent to second ends of the light emitting elements.

The alignment lines may include a first alignment line connected to the first electrode, and a second alignment line connected to the second electrode.

In an embodiment, the applying of the alignment voltages to the alignment lines may include applying a first alignment voltage to the first alignment line, and applying a second alignment voltage to the second alignment line.

The first alignment voltage may be a ground voltage, and the second alignment voltage may be an alternating current voltage.

Details of various embodiments are included in the detailed descriptions and drawings.

In accordance with the above-mentioned embodiments, a dummy partition wall and/or a dummy electrode that is identical or similar to a partition wall and/or an electrode of a pixel may be formed in a dummy pixel. Therefore, a spot defect resulting from a difference in density of the partition wall and/or the electrode may be minimized from occurring in a display area.

The effects of the disclosure are not limited by the foregoing, and other various effects are anticipated herein.

### BRIEF DESCRIPTION OF THE DRAWINGS

The above and other aspects and features of the disclosure will become more apparent by describing in detail embodiments thereof with reference to the attached drawings, in which:

FIG. 1 is a schematic perspective view illustrating a light emitting element in accordance with an embodiment.

FIG. 2 is a schematic cross-sectional view illustrating the light emitting element in accordance with an embodiment.

FIG. 3 is a schematic plan view illustrating a display device in accordance with an embodiment.

FIG. 4 is a schematic plan view illustrating a mother substrate including the display device in accordance with an embodiment.

FIG. 5 is a schematic diagram of an equivalent circuit of a pixel in accordance with an embodiment.

FIGS. 6 and 7 are schematic plan views illustrating a pixel in accordance with an embodiment.

FIG. 8 is a schematic cross-sectional view taken along line A-A′ of FIG. 6.

FIG. 9 is a schematic cross-sectional view taken along line B-B′ of FIG. 6.

FIG. 10 is a schematic cross-sectional view taken along line C-C′ of FIG. 7.

FIG. 11 is a schematic cross-sectional view taken along line D-D′ of FIG. 7.

FIG. 12 is a schematic plan view illustrating a dummy pixel in accordance with an embodiment.

FIG. 13 is a schematic cross-sectional view taken along line E-E′ of FIG. 12.

FIG. 14 is a schematic cross-sectional view illustrating first to third pixels in accordance with an embodiment.

FIG. 15 is a schematic cross-sectional view illustrating a pixel in accordance with an embodiment.

FIGS. 16 to 23 are schematic cross-sectional views illustrating, by process steps, a method of fabricating the display device in accordance with an embodiment.

### DETAILED DESCRIPTION OF THE EMBODIMENTS

Advantages and features of the disclosure, and methods for achieving the same will be understood with reference to embodiments described later in detail together with the accompanying drawings. The disclosure is not limited to the following embodiments, and various modifications are possible. These embodiments are provided so that this disclosure will be thorough and complete and will fully convey the disclosure to those skilled in the art, and the disclosure will also be defined by the appended claims.

The terminology used herein is for the purpose of describing embodiments and is not intended to be limiting of embodiments.

In the drawings, sizes, thicknesses, ratios, and dimensions of the elements may be exaggerated for ease of description and for clarity. Like numbers refer to like elements throughout.

In this specification, the terms of a singular form may include plural forms unless specifically mentioned. For example, as used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will be further understood that the terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

Furthermore, the term “coupling” or “connection” may comprehensively refer to physical and/or electrical coupling or connection. The term “coupling” or “connection” may comprehensively refer to direct or indirect coupling or connection and integral or non-integral coupling or connection.

It will be understood that when an element or a layer is referred to as being “on” another element or a layer, it can be directly on, connected to, or coupled to the other element or the layer, or one or more intervening elements or layers may be present. Like reference numerals refer to like elements throughout.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

It will be understood that, although the terms “first”, “second”, etc. may be used herein to describe various elements, these elements should not be limited by these terms. These terms are only used to distinguish one element from another element. For instance, a first element discussed below could be termed a second element without departing from the teachings of the disclosure.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the disclosure will be described in detail with reference to the accompanying drawings.

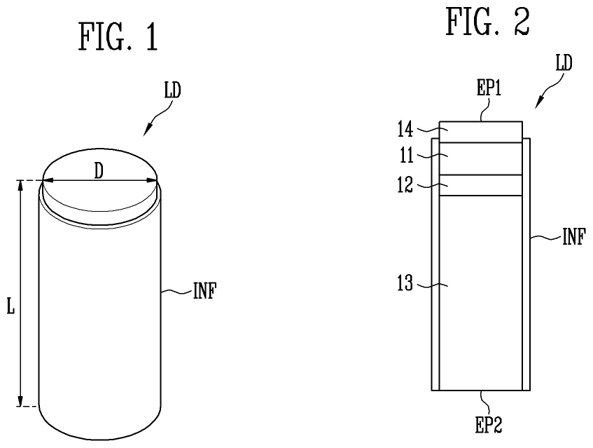

FIG. 1 is a perspective view illustrating a light emitting element in accordance with an embodiment. FIG. 2 is a schematic cross-sectional view illustrating the light emitting element in accordance with an embodiment. Although FIGS. 1 and 2 illustrate a column-type light emitting element LD, the type and/or shape of the light emitting element LD is not limited thereto.

Referring to FIGS. 1 and 2, the light emitting element LD may include a first semiconductor layer 11, an active layer 12, a second semiconductor layer 13, and/or an electrode layer 14.

The light emitting element LD may be provided in the form of a column extending in one direction or a direction. The light emitting element LD may include a first end EP1 and a second end EP2. One of the first and second semiconductor layers 11 and 13 may be disposed on the first end EP1 of the light emitting element LD. The other one of the first and second semiconductor layers 11 and 13 may be disposed on the second end EP2 of the light emitting element LD. For example, the first semiconductor layer 11 may be disposed on the first end EP1 of the light emitting element LD, and the second semiconductor layer 13 may be disposed on the second end EP2 of the light emitting element LD.

In an embodiment, the light emitting element LD may be a light emitting element fabricated in a column shape by an etching scheme or the like within the spirit and the scope of the disclosure. In the specification, the term “column-type” embraces a rod-like shape and a bar-like shape such as a cylindrical shape and a prismatic shape having an aspect ratio greater than 1, and the cross-sectional shape thereof is not limited.

The light emitting element LD may have a small size corresponding to a range from the nanometer scale to the micrometer scale. For example, the light emitting element LD may have a diameter D (or a width) and/or a length L ranging from the nanometer scale to the micrometer scale. However, the size of the light emitting element LD is not limited thereto, and the size of the light emitting element LD may be changed in various ways depending on design conditions of various devices, for example, a display device, using a light emitting device with the light emitting element LD as a light source.

The first semiconductor layer 11 may be a first conductive semiconductor layer. For example, the first semiconductor layer 11 may include a p-type semiconductor layer. For instance, the first semiconductor layer 11 may include a p-type semiconductor layer which may include any one semiconductor material of InAlGaN, GaN, AlGaN, InGaN, or AlN, and is doped with a first conductive dopant such as Mg. However, the material for forming the first semiconductor layer 11 is not limited thereto, and the first semiconductor layer 11 may be formed of various other materials.

The active layer 12 may be disposed between the first semiconductor layer 11 and the second semiconductor layer 13. The active layer 12 may include any one structure of a single well structure, a multi-well structure, a single-quantum well structure, a multi-quantum well (MQW) structure, a quantum dot structure, and a quantum line structure, but the disclosure is not limited thereto. The active layer 12 may include GaN, InGaN, InAlGaN, AlGaN, or AlN. Various other materials may be used to form the active layer 12.

If a voltage equal to or greater than a threshold voltage is applied between the opposite ends of the light emitting element LD, the light emitting element LD may emit light by coupling of electron-hole pairs in the active layer 12. Since light emission of the light emitting element LD can be controlled based on the foregoing principle, the light emitting element LD may be used as a light source of various light emitting devices as well as a pixel of the display device.

The second semiconductor layer 13 may be disposed on the active layer 12 and include a semiconductor layer of a type different from that of the first semiconductor layer 11. The second semiconductor layer 13 may include an n-type semiconductor layer. For instance, the second semiconductor layer 13 may include an n-type semiconductor layer which may include any one semiconductor material of InAlGaN, GaN, AlGaN, InGaN, and AlN, and is doped with a second conductive dopant such as Si, Ge, or Sn. However, the material for forming the second semiconductor layer 13 is not limited thereto, and the second semiconductor layer 13 may be formed of various other materials.

The electrode layer 14 may be disposed on the first end EP1 and/or the second end EP2 of the light emitting element LD. Although FIG. 2 illustrates the case where the electrode layer 14 is formed on the first semiconductor layer 11, the disclosure is not limited thereto. For example, a separate electrode layer may be further disposed on the second semiconductor layer 13.

The electrode layer 14 may include transparent metal or transparent metal oxide. For example, the electrode layer 14 may include at least one of indium tin oxide (ITO), indium zinc oxide (IZO), and zinc tin oxide (ZTO), but the disclosure is not limited thereto. As such, in case that the electrode layer 14 is formed of transparent metal or transparent metal oxide, light generated from the active layer 12 of the light emitting element LD may be emitted out of the light emitting element LD through the electrode layer 14.

An insulating layer INF may be provided on a surface of the light emitting element LD. The insulating layer INF may be disposed on or directly disposed on a surface of the first semiconductor layer 11, a surface of the active layer 12, a surface of the second semiconductor layer 13, and/or a surface of the electrode layer 14. The insulating layer INF may allow the first and second ends EP1 and EP2 of the light emitting element LD that have different polarities to be exposed. In an embodiment, the insulating layer INF may allow a sidewall of the electrode layer 14 and/or the second semiconductor layer 13 disposed adjacent to the first and second ends EP1 and EP2 of the light emitting element LD to be exposed.

The insulating layer INF may prevent the active layer 12 from short-circuiting due to making contact with conductive material except the first and second semiconductor layers 11 and 13. Furthermore, the insulating layer INF may minimize a surface defect of the light emitting elements LD, thus enhancing the lifetime and emission efficiency of the light emitting elements LD.

The insulating film INF may include at least one of silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium dioxide (TiOₓ). For example, the insulating layer INF may have a double layer structure, and respective layers that form the double layer structure may include different materials. For example, the insulating layer INF may have a double layer structure formed of aluminum oxide (AlOₓ) and silicon oxide (SiOₓ), but the disclosure is not limited thereto. In an embodiment, the insulating layer INF may be omitted.

A light emitting device including the light emitting element LD described above may be used not only in a display device but also in various devices which requires a light source. For instance, light emitting elements LD may be disposed in each pixel of a display panel, so that the light emitting elements LD may be used as a light source of the pixel. However, the application field of the light emitting element LD is not limited to the above-mentioned examples. For example, the light emitting element LD may also be used in other types of devices such as a lighting device, which requires a light source.

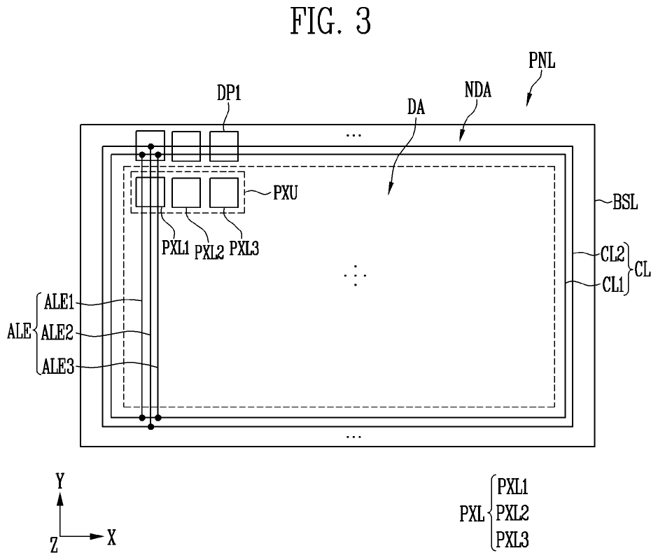

FIG. 3 is a schematic plan view illustrating a display device in accordance with an embodiment.

FIG. 3 illustrates a display device, for example, a display panel PNL provided in the display device, as an example of an electronic device which may use, as a light source, the light emitting element LD described in the embodiments of FIGS. 1 and 2.

For the sake of explanation, FIG. 3 simply illustrates the structure of the display panel PNL in accordance with an embodiment, focused on a display area DA. In an embodiment, although not illustrated, at least one driving circuit (for example, at least one of a scan driver and a data driver), lines, and/or pads may be further disposed on the display panel PNL.

Referring to FIG. 3, the display panel PNL and a base layer BSL (or a substrate) for forming the display panel PNL may include a display area DA for displaying an image, and a non-display area NDA other than the display area DA. The display area DA may form a screen on which an image is displayed. The non-display area NDA may be an area other than the display area DA.

A pixel unit PXU may be disposed in the display area DA. The pixel unit PXU may include a first pixel PXL1, a second pixel PXL2, and/or a third pixel PXL3. Hereinafter, the term “pixel PXL” or “pixels PXL” will be used to arbitrarily designate at least one pixel of the first pixel PXL1, the second pixel PXL2, and the third pixel PXL3, or collectively designate two or more kinds of pixels.

The pixels PXL may be regularly arranged or disposed according to a stripe or PENTILE™ arrangement structure. The arrangement structure of the pixels PXL is not limited thereto, and the pixels PXL may be arranged in the display area DA in various structures and/or schemes.

In an embodiment, two or more kinds of pixels PXL which emit different colors of light may be disposed in the display area DA. For example, first pixels PXL1 that emit a first color of light, second pixels PXL2 that emit a second color of light, and third pixels PXL3 that emit a third color of light may be arranged in the display area DA. At least one first pixel PXL1, at least one second pixel PXL2, and at least one third pixel PXL3 that are disposed adjacent to each other may form one pixel unit PXU which may emit various colors of light. For example, each of the first to third pixels PXL1, PXL2, and PXL3 may be a pixel that emits a given color of light. In an embodiment, the first pixel PXL1 may be a red pixel that emits red light, a second pixel PXL2 may be a green pixel that emits green light, and a third pixel PXL3 may be a blue light that emits blue light. However, the disclosure is not limited thereto.

In an embodiment, the first pixel PXL1, the second pixel PXL2, and the third pixel PXL3 may respectively include light emitting elements that emit a same color of light, and color conversion layers and/or color filter layers pertaining to different colors may be disposed on the respective light emitting elements so that the first pixel PXL1, the second pixel PXL2, and the third pixel PXL3 may respectively emit the first color of light, the second color of light, and the third color of light. In an embodiment, the first pixel PXL1, the second pixel PXL2, and the third pixel PXL3 may respectively include, as light sources, a light emitting element related to the first color, a light emitting element related to the second color, and a light emitting element related to the third color, and thus may respectively emit the first color of light, the second color of light, and the third color of light. However, the colors, the types, and/or the number of pixels PXL that form each pixel unit PXU are not particularly limited. In other words, the color of light to be emitted from each pixel PXL may be changed in various ways.

The pixel PXL may include at least one light source which is driven by a control signal (for example, a scan signal and a data signal) and/or a power supply (for example, a first power supply and a second power supply). In an embodiment, the light source may include at least one light emitting element LD in accordance with any one of the embodiments of FIGS. 1 and 2, for example, subminiature column-type light emitting elements LD having a small size corresponding to a range from the nanometer scale to the micrometer scale. However, the disclosure is not limited thereto, and different types of light emitting elements LD may be used as a light source of the pixel PXL.

In an embodiment, each pixel PXL may be formed of an active pixel. However, the types, structures, and/or driving schemes of the pixels PXL applicable to the display device are not particularly limited. For example, each pixel PXL may be formed of a pixel for passive or active light emitting display devices which have various structures and/or may be operated in various driving schemes.

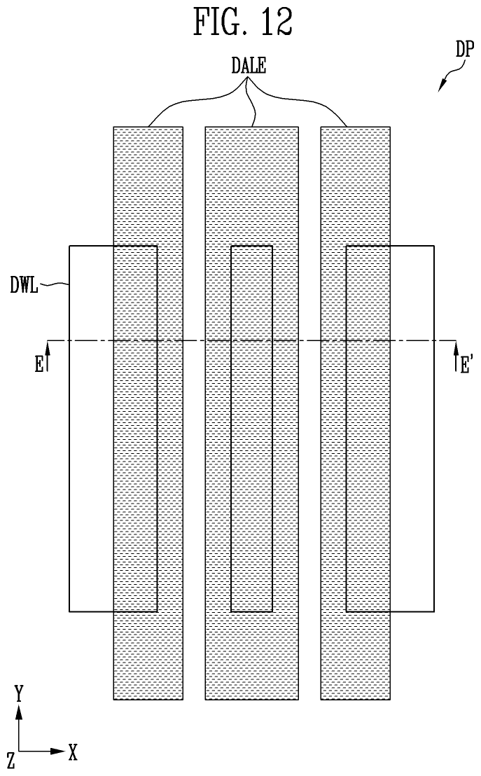

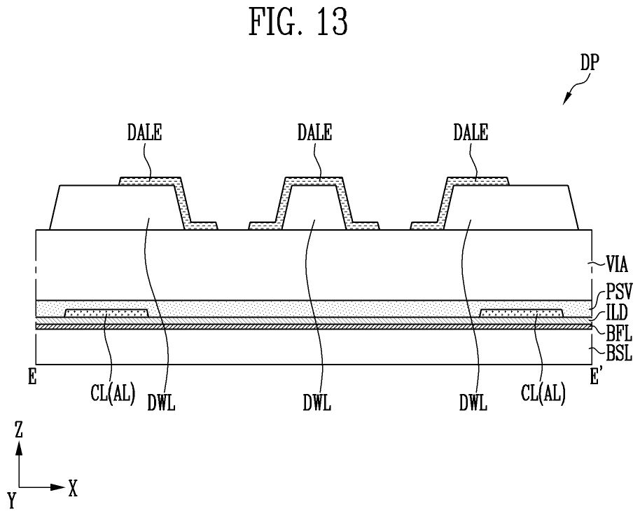

The non-display area NDA may be disposed around the display area DA. First dummy pixels DP1 may be disposed in the non-display area NDA. The first dummy pixels DP1 may be formed to minimize a side effect such as a process deviation or a loading effect, which may occur during a process of fabricating the display device, and may be formed to enclose the pixels PXL and thus function as a kind of buffer zone. For example, patterns identical or similar to patterns of the pixels PXL formed in the display area DA may be uniformly formed in the first dummy pixels DP1, so that a phenomenon in which a spot defect occurs in the display area DA due to a difference in density of the patterns can be minimized. Detailed descriptions pertaining to the foregoing will be made with reference to FIG. 12.

The first dummy pixels DP1 may be arranged in rows or columns. However, the arrangement structure of the first dummy pixels DP1 is not limited thereto. The first dummy pixels DP1 may be arranged in the non-display area NDA in various structures and/or schemes.

In an embodiment, conductive lines CL may be disposed in the non-display area NDA. The conductive lines CL may overlap the first dummy pixels DP1. In other words, electrodes and/or patterns that form the first dummy pixels DP1 may be formed on the conductive lines CL. The conductive lines CL may be disposed to at least partially enclose the display area DA.

The conductive lines CL may include a first conductive line CL1 and a second conductive line CL2. The first conductive line CL1 may be electrically connected to a first power pad, thus functioning to provide, to the pixel PXL, first power applied to the first power pad. Furthermore, the first conductive line CL1 may be connected to a first alignment pad provided on the mother substrate (or a substrate) at the step of aligning the light emitting elements LD in the pixel PXL during the process of fabricating the display panel PNL and provide a first alignment voltage applied to the first alignment pad to the first electrode ALE1 and/or the third electrode ALE3 of the pixels PXL. To this end, the first conductive line CL1 may be connected to the first electrode ALE1 and/or the third electrode ALE3 of each of the pixels PXL.

The second conductive line CL2 may be electrically connected to a second power pad, thus functioning to provide, to the pixel PXL, second power applied to the second power pad. Furthermore, the second conductive line CL2 may be connected to a second alignment pad provided on the mother substrate at the step of aligning the light emitting elements LD in the pixel PXL during the process of fabricating the display panel PNL and provide a second alignment voltage applied to the second alignment pad to the second electrode ALE2 of the pixels PXL. To this end, the second conductive line CL2 may be connected to the second electrode ALE2 of each of the pixels PXL. For example, the first alignment voltage may be a ground voltage, and the second alignment voltage may be an AC voltage, but the disclosure is not limited thereto.

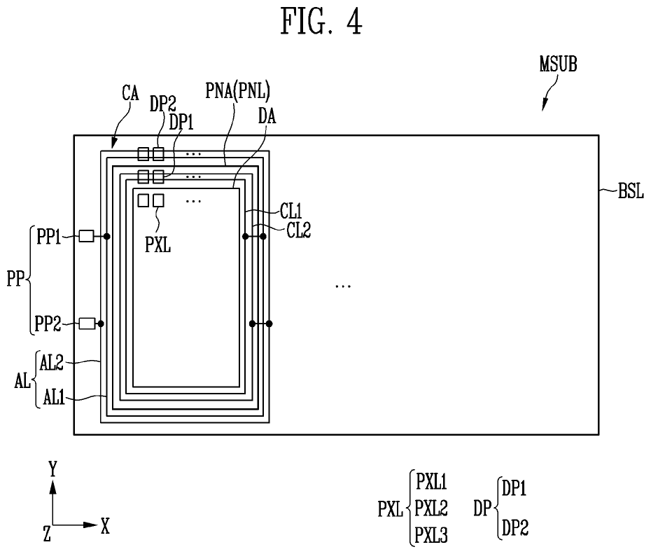

FIG. 4 is a schematic plan view illustrating a mother substrate MSUB including the display device in accordance with an embodiment.

Referring to FIG. 4, the mother substrate MSUB may be a mother board which is a base of the display panel PNL. For example, the mother substrate MSUB may include a panel area PNA and a cutting area CA. The cutting area CA may enclose the panel area PNA. The display panel PNL corresponding to the panel area PNA may be manufactured by cutting the cutting area CA of the mother substrate MSUB.

Second dummy pixels DP2 may be disposed in the cutting area CA. The second dummy pixels DP2 may be formed to minimize a side effect such as a process deviation or a loading effect, which may occur during a process of fabricating the display device, and thus function as a kind of buffer zone. For example, patterns identical or similar to patterns of the pixels PXL formed in the display area DA may be uniformly formed in the second dummy pixels DP2, so that a phenomenon in which a spot defect occurs in the display area DA due to a difference in density of the patterns can be minimized.

The second dummy pixels DP2 may be arranged in rows or columns. However, the arrangement structure of the second dummy pixels DP2 is not limited thereto. The second dummy pixels DP2 may be arranged in the cutting area CA in various structures and/or schemes. The second dummy pixels DP2 may have structures identical or similar to that of the first dummy pixels DP1. Detailed descriptions pertaining thereto will be made with reference to FIGS. 12 and 13.

In an embodiment, alignment pads PP and alignment lines AL may be disposed in the cutting area CA. The alignment lines AL may overlap the second dummy pixels DP2. In other words, electrodes and/or patterns that form the second dummy pixels DP2 may be formed on the alignment lines AL. The alignment lines AL may be disposed to at least partially enclose the panel area PNA.

The alignment pads PP may include a first alignment pad PP1 and a second alignment pad PP2. The alignment lines AL may include a first alignment line AL1 connected to the first alignment pad PP1, and a second alignment line AL2 connected to the second alignment pad PP2. The first alignment line AL1 may be connected with the first conductive line CL1 and provide, to the pixels PXL, a first alignment voltage applied to the first alignment pad PP1. The second alignment line AL2 may be connected with the second conductive line CL2 and provide, to the pixels PXL, a second alignment voltage applied to the second alignment pad PP2.

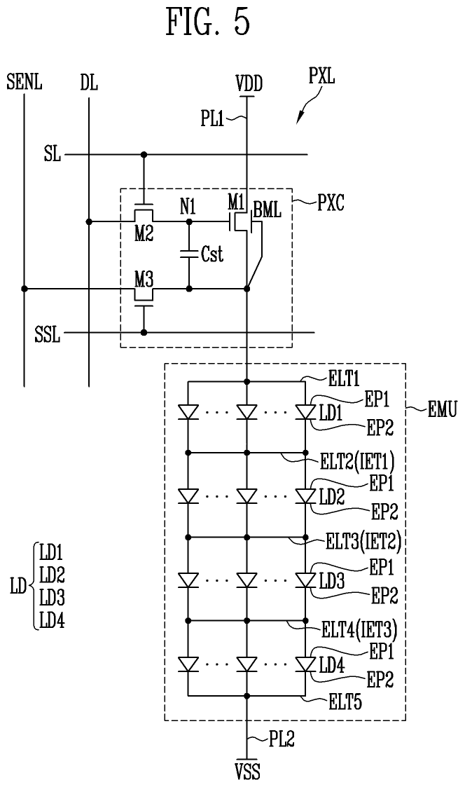

FIG. 5 is a schematic diagram of an equivalent circuit of a pixel PXL in accordance with an embodiment.

The pixel PXL illustrated in FIG. 5 may be any one of the first pixel PXL1, the second pixel PXL2, and the third pixel PXL3 that are provided on the display panel PNL of FIG. 3. The first pixel PXL1, the second pixel PXL2, and the third pixel PXL3 may have identical or similar structures.

Referring to FIG. 5, each pixel PXL may further include an emission component EMU to generate light having luminance corresponding to a data signal, and a pixel circuit PXC to drive the emission component EMU.

The pixel circuit PXC may be connected between a first power supply VDD and the emission component EMU. Furthermore, the pixel circuit PXC may be connected to a scan line SL and a data line DL of the corresponding pixel PXL, and control the operation of the emission component EMU in response to a scan signal and a data signal supplied from the scan line SL and the data line DL. Furthermore, the pixel circuit PXC may be selectively further connected to a sensing signal line SSL and a sensing line SENL.

The pixel circuit PXC may include at least one transistor and at least one capacitor. For example, the pixel circuit PXC may include a first transistor M1, a second transistor M2, a third transistor M3, and a storage capacitor Cst.

The first transistor M1 may be connected between the first power supply VDD and a first connection electrode ELT1. A gate electrode of the first transistor M1 may be connected to the first node N1. The first transistor M1 may control driving current to be supplied to the emission component EMU in response to a voltage of the first node N1. In other words, the first transistor M1 may be a driving transistor to control the driving current of the pixel PXL.

In an embodiment, the first transistor M1 may selectively include a bottom conductive layer BML (referred also to as “bottom electrode”, “back gate electrode” or “bottom light shielding layer”). The gate electrode of the first transistor M1 and the bottom conductive layer BML may overlap each other with an insulating layer interposed therebetween. In an embodiment, the bottom conductive layer BML may be connected to one electrode of the first transistor M1, for example, a source or drain electrode of the first transistor M1.

In case that the first transistor M1 may include the bottom conductive layer BML, a back-biasing technique (or a sync technique) may be used, the back-biasing technique being a technique of shifting a threshold voltage of the first transistor M1 in a negative direction or a positive direction by applying a bank-biasing voltage to the bottom conductive layer BML of the first transistor M1 in case that the pixel PXL is driven. For example, a source-sync technique may be used by connecting the bottom conductive layer BML to the source electrode of the first transistor M1, so that the threshold voltage of the first transistor M1 may be shifted in the negative direction or the positive direction. In case that the bottom conductive layer BML is disposed under or below a semiconductor pattern that forms a channel of the first transistor M1, the bottom conductive layer BML may function as a light shielding pattern and stabilize operating characteristics of the first transistor M1. However, the function and/or application scheme of the bottom conductive layer BML is not limited thereto.

The second transistor M2 may be connected between the data line DL and the first node N1. A gate electrode of the second transistor M2 may be connected to the scan line SL. In case that a scan signal having a gate-on voltage (for example, a high-level voltage) is supplied from the scan line SL, the second transistor M2 may be turned on to connect the data line DL with the first node N1.

During each frame period, a data signal of the corresponding frame may be supplied to the data line DL, and the data signal may be transmitted to the first node N1 through the second transistor M2 that is turned on during a period during which the scan signal having the gate-on voltage is supplied to the scan line SL. In other words, the second transistor M2 may be a switching transistor to transmit each data signal to the interior of the pixel PXL.

One electrode of the storage capacitor Cst may be connected to the first node N1, and the other electrode thereof may be connected to a second electrode of the first transistor M1. The storage capacitor Cst may be charged with a voltage corresponding to a data signal to be supplied to the first node N1 during each frame period.

The third transistor M3 may be connected between the first connection electrode ELT1 (or the second electrode of the first transistor M1) and the sensing line SENL. A gate electrode of the third transistor M3 may be connected to the sensing signal line SSL. The third transistor M3 may transmit a voltage value applied to the first connection electrode ELT1, to the sensing line SENL in response to a sensing signal supplied to the sensing signal line SSL. The voltage value transmitted through the sensing line SENL may be provided to an external circuit (for example, a timing controller). The external circuit may extract information about characteristics of each pixel PXL (for example, a threshold voltage of the first transistor M1, etc.) based on the provided voltage value. The extracted characteristic information may be used to convert image data to compensate for a deviation in characteristics between the pixels PXL.

In an embodiment, the sensing signal may be a signal equal to or different from the above-mentioned scan signal. In case that the sensing signal is a signal equal to the scan signal, the sensing signal line SSL may be selectively integrated with the scan line SL.

Although FIG. 5 illustrates the case where all of the transistors included in the pixel circuit PXC are formed of n-type transistors, the disclosure is not certainly limited thereto. For example, at least one of the first, second, and third transistors M1, M2, and M3 may be changed to a p-type transistor.

The structure and driving scheme of the pixel PXL may be changed in various ways. For instance, the pixel circuit PXC may not only be formed of the pixel circuit of the embodiment illustrated in FIG. 5 but may also be formed of a pixel circuit which may have various structures and/or be operated in various driving schemes.

For example, the pixel circuit PXC may not include the third transistor M3. Furthermore, the pixel circuit PXC may further include other circuit elements such as a compensation transistor to compensate for the threshold voltage of the first transistor M1, an initialization transistor to initialize the voltage of the first node N1 and/or the first connection electrode ELT1, an emission control transistor to control a period during which driving current is supplied to the emission component EMU, and/or a boosting capacitor to boost the voltage of the first node N1.

The emission component EMU may include at least one light emitting element LD, for example, light emitting elements LD, connected between the first power supply VDD and the second power supply VSS.

For example, the emission component EMU may include a first connection electrode ELT1 connected to the first power supply VDD by the pixel circuit PXC and the first power line PL1, a fifth connection electrode ELT5 connected to the second power supply VSS by the second power line PL2, and light emitting elements LD connected between the first and fifth connection electrodes ELT1 and ELT5.

The first power supply VDD and the second power supply VSS may have different potentials to allow the light emitting elements LD to emit light. For example, the first power supply VDD may be set as a high-potential power supply, and the second power supply VSS may be set as a low-potential power supply.

In an embodiment, the emission component EMU may include at least one serial stage. Each serial stage may include a pair of electrodes (for example, two electrodes), and at least one light emitting element LD connected in a forward direction between the pair of electrodes. Here, the number of serial stages that form the emission component EMU and the number of light emitting elements LD that form each serial stage are not particularly limited. For example, the numbers of light emitting elements LD that form the respective serial stages may be identical to or different from each other. The number of light emitting elements LD of each serial stage is not particularly limited.

For example, the emission component EMU may include a first serial stage including at least one first light emitting element LD1, a second serial stage including at least one second light emitting element LD2, a third serial stage including at least one third light emitting element LD3, and a fourth serial stage including at least one fourth light emitting element LD4.

The first serial stage may include a first connection electrode ELT1, a second connection electrode ELT2, and at least one first light emitting element LD1 connected between the first and second connection electrodes ELT1 and ELT2. Each first light emitting element LD1 may be connected in the forward direction between the first and second connection electrodes ELT1 and ELT2. For example, a first end EP1 of the first light emitting element LD1 may be connected to the first connection electrode ELT1. A second end EP2 of the first light emitting element LD1 may be connected to the second connection electrode ELT2.

The second serial stage may include the second connection electrode ELT2, a third connection electrode ELT3, and at least one second light emitting element LD2 connected between the second and third connection electrodes ELT2 and ELT3. Each second light emitting element LD2 may be connected in the forward direction between the second and third connection electrodes ELT2 and ELT3. For example, a first end EP1 of the second light emitting element LD2 may be connected to the second connection electrode ELT2. A second end EP2 of the second light emitting element LD2 may be connected to the third connection electrode ELT3.

The third serial stage may include the third connection electrode ELT3, a fourth connection electrode ELT4, and at least one third light emitting element LD3 connected between the third and fourth connection electrodes ELT3 and ELT4. Each third light emitting element LD3 may be connected in the forward direction between the third and fourth connection electrodes ELT3 and ELT4. For example, a first end EP1 of the third light emitting element LD3 may be connected to the third connection electrode ELT3. A second end EP2 of the third light emitting element LD3 may be connected to the fourth connection electrode ELT4.

The fourth serial stage may include the fourth connection electrode ELT4, the fifth connection electrode ELT5, and at least one fourth light emitting element LD4 connected between the fourth and fifth connection electrodes ELT4 and ELT5. Each fourth light emitting element LD4 may be connected in the forward direction between the fourth and fifth connection electrodes ELT4 and ELT5. For example, a first end EP1 of the fourth light emitting element LD4 may be connected to the fourth connection electrode ELT4. A second end EP2 of the fourth light emitting element LD4 may be connected to the fifth connection electrode ELT5.

The 1st electrode of the emission component EMU, for example, the first connection electrode ELT1, may be an anode electrode of the emission component EMU. The last electrode of the emission component EMU, for example, the fifth connection electrode ELT5, may be a cathode electrode of the emission component EMU.

The other electrodes of the emission component EMU, for example, the second connection electrode ELT2, the third connection electrode ELT3, and/or the fourth connection electrode ELT4, each may form an intermediate electrode. For example, the second connection electrode ELT2 may form a first intermediate electrode IET1. The third connection electrode ELT3 may form a second intermediate electrode IET2. The fourth connection electrode ELT4 may form a third intermediate electrode IET3.

In case that the light emitting elements LD are connected to have a serial/parallel structure, power efficiency may be enhanced, compared to the case where an equal number of light emitting elements LD are connected only in parallel to each other. Furthermore, in the pixel PXL in which the light emitting elements LD are connected to have the serial/parallel structure, even if a short-circuit defect or the like occurs in some or a number of serial stages, sufficient luminance can be expressed by the light emitting elements LD of the other serial stages, so that the probability of occurrence of a black spot defect in the pixel PXL can be reduced. However, the disclosure is not limited thereto. The emission component EMU may be formed by connecting the light emitting elements LD only in series. By way of example, the emission component EMU may be formed by connecting the light emitting elements LD only in parallel.

Each of the light emitting elements LD may include a first end EP1 (for example, a p-type end) connected to the first power supply VDD via at least one electrode (for example, the first connection electrode ELT1), the pixel circuit PXC, and/or the first power line PL1, and a second end EP2 (for example, an n-type end) connected to the second power supply VSS via at least another electrode (for example, the fifth connection electrode ELT5), and the second power line PL2. In other words, the light emitting elements LD may be connected in the forward direction between the first power supply VDD and the second power supply VSS. The light emitting elements LD connected in the forward direction may form valid light sources of the emission component EMU.

The light emitting elements LD may emit, in case that driving current is supplied thereto through the corresponding pixel circuit PXC, light having luminance corresponding to the driving current. For example, during each frame period, the pixel circuit PXC may supply driving current corresponding to a gray scale value to be expressed in the corresponding frame to the emission component EMU. Hence, the light emitting elements LD may emit light having luminance corresponding to the driving current, so that the emission component EMU may express the luminance corresponding to the driving current.

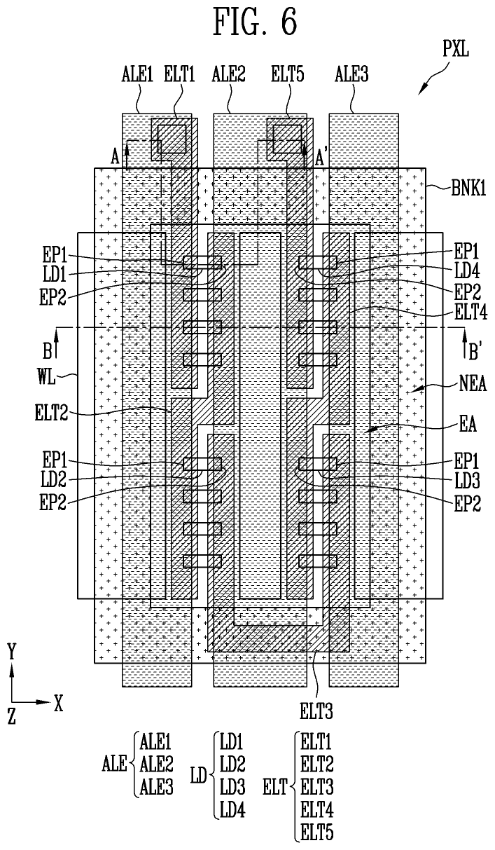

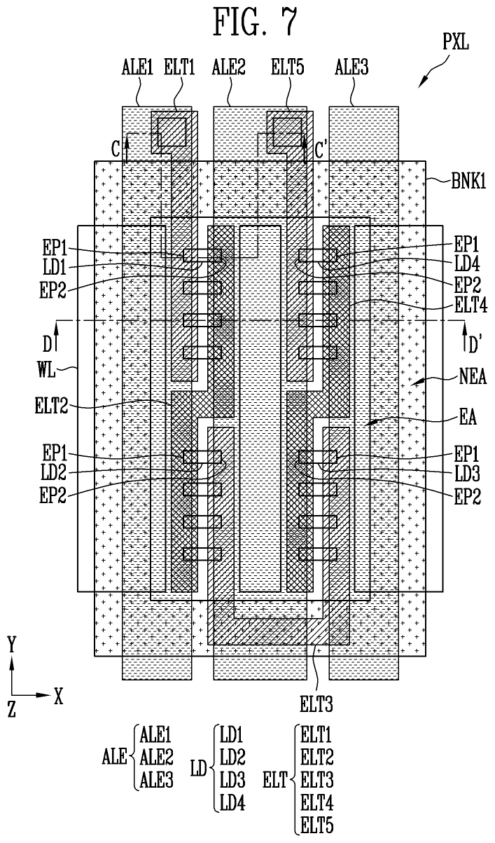

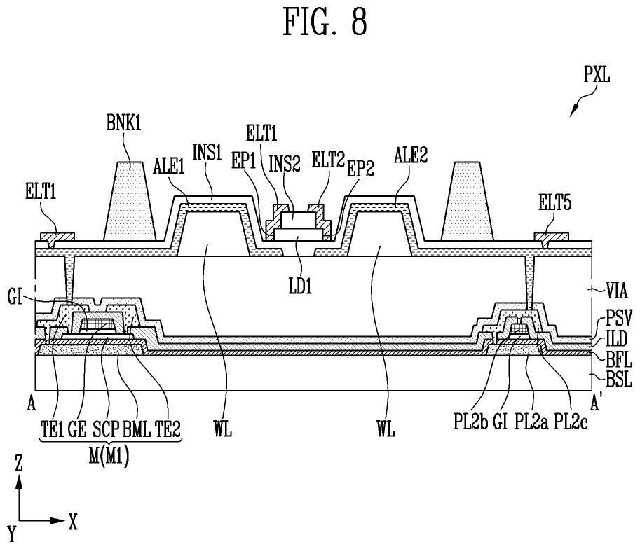

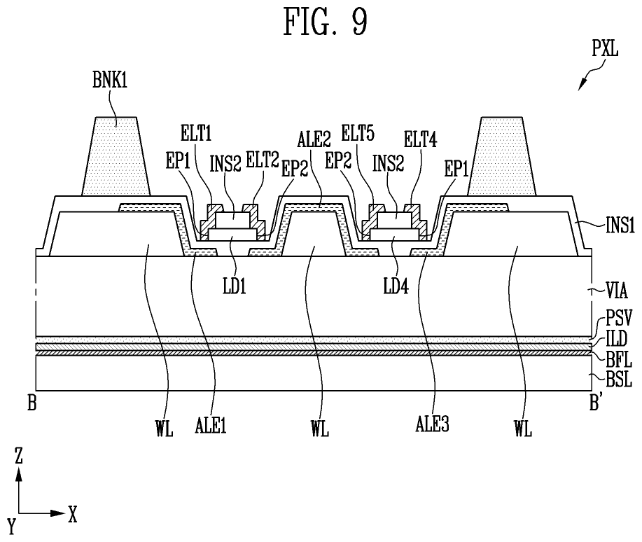

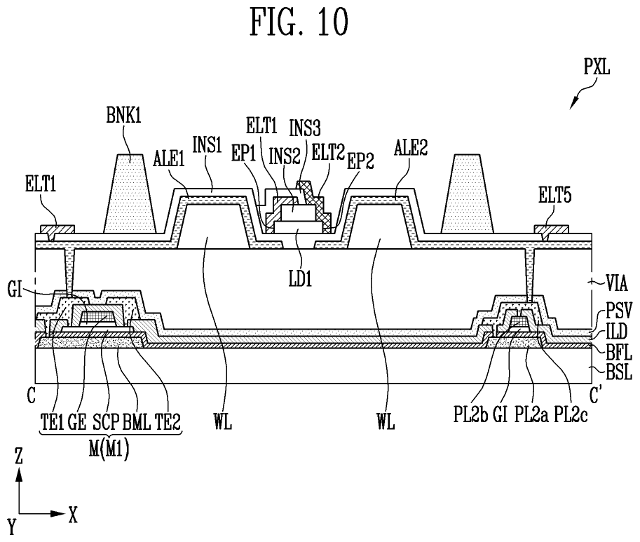

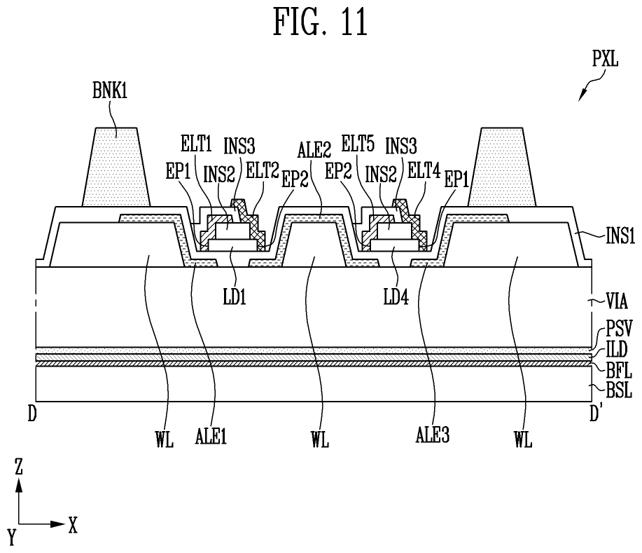

FIGS. 6 and 7 are schematic plan views illustrating a pixel PXL in accordance with an embodiment. FIG. 8 is a schematic cross-sectional view taken along line A-A′ of FIG. 6. FIG. 9 is a schematic cross-sectional view taken along line B-B′ of FIG. 6. FIG. 10 is a schematic cross-sectional view taken along line C-C′ of FIG. 7. FIG. 11 is a schematic cross-sectional view taken along line D-D′ of FIG. 7.

For example, the pixel PXL of FIGS. 6 and 7 may be any one of the first to third pixels PXL1, PXL2, and PXL3 that form the pixel unit PXU of FIG. 3, and the first to third pixels PXL1, PXL2, and PXL3 may have identical or similar structures. Although FIGS. 6 and 7 illustrates an embodiment in which, as illustrated in FIG. 5, each pixel PXL may include light emitting elements LD disposed in four serial stages, the number of serial stages in the pixel PXL may be changed in various ways depending on embodiments.

Hereinafter, the term “light emitting element LD” or “light emitting elements LD” will be used to arbitrarily designate at least one light emitting element of the first to fourth light emitting elements LD1, LD2, LD3, and LD4, or collectively designate two or more kinds of light emitting elements. Furthermore, the term “electrode ALE” or “electrodes ALE” will be used to arbitrarily designate at least one of electrodes including the first to third electrodes ALE1, ALE2, and ALE3. The term “connection electrode ELT” or “connection electrode ELT” will be used to arbitrarily designate at least one of electrodes including the first to fifth connection electrodes ELT1, ELT2, ELT3, ELT4, and ELT5.

Referring to FIGS. 6 and 7, each pixel PXL may include an emission area EA and a non-emission area NEA. The emission area EA may be an area which may include light emitting elements LD and is able to emit light. The non-emission area NEA may be disposed to enclose the emission area EA. The non-emission area NEA may be an area where a first bank BNK1 enclosing the emission area EA is provided. The first bank BNK1 may be provided in the non-emission area NEA and be disposed to at least partially enclose the emission area EA.

The first bank BNK1 may include an opening that overlaps the emission area EA. The opening of the first bank BNK1 may provide, at the step of supplying the light emitting elements LD to each pixel PXL, space to which the light emitting elements LD are to be provided. For example, a desired kind and/or amount of light emitting element ink may be supplied to the space defined by the opening of the first bank BNK1.

The first bank BNK1 may include organic material such as acrylic resin, epoxy resin, phenolic resin, polyamide resin, polyimide resin, polyester resin, polyphenylene sulfide resin, or benzocyclobutene (BCB). However, the disclosure is not limited thereto. The first bank BNK1 may include various inorganic materials including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

In an embodiment, the first bank BNK1 may include at least one light shielding and/or reflective material. Therefore, a light leakage between adjacent pixels PXL may be prevented from being caused. For example, the first bank BNK1 may include a black pigment, but the disclosure is not limited thereto.

The pixels PXL each may include partition walls WL, electrodes ALE, light emitting elements LD, and/or connection electrodes ELT.

The partition walls WL may be provided in at least the emission area EA. The partition walls WL may be at least partially provided in the non-emission area NEA. The partition walls WL may extend in a second direction (a Y-axis direction) and be spaced apart from each other in a first direction (an X-axis direction).

The partition walls WL each may partially overlap at least one electrode ALE in at least the emission area EA. For example, the partition walls WL may be respectively provided under or below the electrodes ALE. Since the partition walls WL are provided under or below respective partial areas of the electrodes ALE, the respective partial areas of the electrodes ALE may protrude in an upward direction of the pixel PXL, for example, in a third direction (a Z-axis direction), in the areas where the partition walls WL are formed. In case that the partition walls WL and/or the electrodes ALE include reflective material, a reflective wall structure may be formed around the light emitting elements LD. Hence, light emitted from the light emitting elements LD may be emitted in the upward direction of the pixel PXL (for example, in a frontal direction of the display panel PNL including a given viewing angle range), so that the light output efficiency of the display panel PNL may be improved.

The electrodes ALE may be provided in at least the emission area EA. The electrodes ALE may extend in the second direction (the Y-axis direction) and be spaced apart from each other in the first direction (the X-axis direction).

The first to third electrodes ALE1, ALE2, and ALE3 each may extend in the second direction (the Y-axis direction), and may be spaced apart from each other in the first direction (the X-axis direction) and successively disposed. Some or a number of the electrodes ALE may be connected to the pixel circuit (PXC of FIG. 5) and/or a power line through a contact hole. For example, the first electrode ALE1 may be connected to the pixel circuit PXC and/or the first power line PL1 through a contact hole, and the second electrode ALE2 may be connected to the second power line PL2 through a contact hole.

In an embodiment, some or a number of the electrodes ALE may be electrically connected to some or a number of the connection electrodes ELT through a contact hole. For example, the first electrode ALE1 may be electrically connected to the first connection electrode ELT1 through a contact hole. The second electrode ALE2 may be electrically connected to the fifth connection electrode ELT5 through a contact hole.

A pair of alignment electrodes ALE adjacent to each other may be supplied with different signals at the step of aligning the light emitting elements LD. For example, in case that the first to third electrodes ALE1, ALE2, and ALE3 are successively arranged in the first direction (the X-axis direction), the first electrode ALE1 and the second electrode ALE2 may be supplied with different alignment voltages, and the second electrode ALE2 and the third electrode ALE3 may be supplied with different alignment voltages. Although the first electrode ALE1 and the third electrode ALE3 are supplied with a same alignment voltage, the disclosure is limited thereto.

The light emitting elements LD may be aligned between a pair of electrodes ALE in each emission area EA. Furthermore, the light emitting elements LD each may be electrically connected between a pair of connection electrodes ELT.

The first light emitting element LD1 may be aligned between the first and second electrodes ALE1 and ALE2. The first light emitting element LD1 may be electrically connected between the first and second connection electrodes ELT1 and ELT2. For example, the first light emitting element LD1 may be aligned in first areas (for example, upper end areas) of the first and second electrodes ALE1 and ALE2. The first end EP1 of the first light emitting element LD1 may be electrically connected to the first connection electrode ELT1. The second end EP2 of the first light emitting element LD1 may be electrically connected to the second connection electrode ELT2.

The second light emitting element LD2 may be aligned between the first and second electrodes ALE1 and ALE2. The second light emitting element LD2 may be electrically connected between the second and third connection electrodes ELT2 and ELT3. For example, the second light emitting element LD2 may be aligned in second areas (for example, lower end areas) of the first and second electrodes ALE1 and ALE2. The first end EP1 of the second light emitting element LD2 may be electrically connected to the second connection electrode ELT2. The second end EP2 of the second light emitting element LD2 may be electrically connected to the third connection electrode ELT3.

The third light emitting element LD3 may be aligned between the second and third electrodes ALE2 and ALE3. The third light emitting element LD3 may be electrically connected between the third and fourth connection electrodes ELT3 and ELT4. For example, the third light emitting element LD3 may be aligned in second areas (for example, lower end areas) of the second and third electrodes ALE2 and ALE3. The first end EP1 of the third light emitting element LD3 may be electrically connected to the third connection electrode ELT3. The second end EP2 of the third light emitting element LD3 may be electrically connected to the fourth connection electrode ELT4.

The fourth light emitting element LD4 may be aligned between the second and third electrodes ALE2 and ALE3. The fourth light emitting element LD4 may be electrically connected between the fourth and fifth connection electrodes ELT4 and ELT5. For example, the fourth light emitting element LD4 may be aligned in first areas (for example, upper end areas) of the second and third electrodes ALE2 and ALE3. The first end EP1 of the fourth light emitting element LD4 may be electrically connected to the fourth connection electrode ELT4. The second end EP2 of the fourth light emitting element LD4 may be electrically connected to the fifth connection electrode ELT5.

For example, the first light emitting element LD1 may be disposed in a left upper end area of the emission area EA. The second light emitting element LD2 may be disposed in a left lower end area of the emission area EA. The third light emitting element LD3 may be disposed in a right lower end area of the emission area EA. The fourth light emitting element LD4 may be disposed in a right upper end area of the emission area EA. Here, the arrangement and/or connection structure of the light emitting elements LD may be changed in various ways depending on the structure of the emission circuit EMU and/or the number of serial stages.

The connection electrodes ELT each may be provided in at least the emission area EA, and be disposed to overlap at least one electrode ALE and/or light emitting element LD. For example, the connection electrodes ELT may be provided on the electrodes ALE and/or the light emitting elements LD in such a way that each of the connection electrodes ELT overlaps the corresponding electrodes ALE and/or the corresponding light emitting elements LD, whereby the connection electrodes ELT may be electrically connected to the light emitting elements LD.

The first connection electrode ELT1 may be disposed on the first area (for example, the upper end area) of the first electrode ALE1 and the first ends EP1 of the first light emitting elements LD1, and thus electrically connected to the first ends EP1 of the first light emitting elements LD1.

The second connection electrode ELT2 may be disposed on the first area (for example, the upper end area) of the second electrode ALE2 and the second ends EP2 of the first light emitting elements LD1, and thus electrically connected to the second ends EP2 of the first light emitting elements LD1. Furthermore, the second connection electrode ELT2 may be disposed on the second area (for example, the lower end area) of the first electrode ALE1 and the first ends EP1 of the second light emitting elements LD2, and thus electrically connected to the first ends EP1 of the second light emitting elements LD2. For example, the second connection electrode ELT2 may electrically connect the second ends EP2 of the first light emitting elements LD1 and the first ends EP1 of the second light emitting elements LD2 to each other in the emission area EA. To this end, the second connection electrode ELT2 may have a bent shape. For example, the second connection electrode ELT2 may have a bent or curved structure on a boundary between an area where at least one first light emitting element LD1 is disposed and an area where at least one second light emitting element LD2 is disposed.

The third connection electrode ELT3 may be disposed on the second area (for example, the lower end area) of the second electrode ALE2 and the second ends EP2 of the second light emitting elements LD2, and thus electrically connected to the second ends EP2 of the second light emitting elements LD2. Furthermore, the third connection electrode ELT3 may be disposed on the second area (for example, the lower end area) of the third electrode ALE3 and the first ends EP1 of the third light emitting elements LD3, and thus electrically connected to the first ends EP1 of the third light emitting elements LD3. For example, the third connection electrode ELT3 may electrically connect the second ends EP2 of the second light emitting elements LD2 and the first ends EP1 of the third light emitting elements LD3 to each other in the emission area EA. To this end, the third connection electrode ELT3 may have a bent shape. For example, the third connection electrode ELT3 may have a bent or curved structure on a boundary between an area where at least one second light emitting element LD2 is disposed and an area where at least one third light emitting element LD3 is disposed.

The fourth connection electrode ELT4 may be disposed on the second area (for example, the lower end area) of the second electrode ALE2 and the second ends EP2 of the third light emitting elements LD3, and thus electrically connected to the second ends EP2 of the third light emitting elements LD3. Furthermore, the fourth connection electrode ELT4 may be disposed on the first area (for example, the upper end area) of the third electrode ALE3 and the first ends EP1 of the fourth light emitting elements LD4, and thus electrically connected to the first ends EP1 of the fourth light emitting elements LD4. For example, the fourth connection electrode ELT4 may electrically connect the second ends EP2 of the third light emitting elements LD3 and the first ends EP1 of the fourth light emitting elements LD4 to each other in the emission area EA. To this end, the fourth connection electrode ELT4 may have a bent shape. For example, the fourth connection electrode ELT4 may have a bent or curved structure on a boundary between an area where at least one third light emitting element LD3 is disposed and an area where at least one fourth light emitting element LD4 is disposed.

The fifth connection electrode ELT5 may be disposed on the first area (for example, the upper end area) of the second electrode ALE2 and the second ends EP2 of the fourth light emitting elements LD4, and thus electrically connected to the second ends EP2 of the fourth light emitting elements LD4.

The first connection electrode ELT1, the third connection electrode ELT3, and/or the fifth connection electrode ELT5 may be formed of an identical conductive layer. Furthermore, the second connection electrode ELT2 and the fourth connection electrode ELT4 may be formed of an identical conductive layer. In an embodiment, as illustrated in FIG. 6, the first to fifth connection electrodes ELT1, ELT2, ELT3, ELT4, and ELT5 may be formed of an identical conductive layer. The first to fifth connection electrodes ELT1, ELT2, ELT3, ELT4, and ELT5 may be simultaneously formed through a same process. As such, in case that the connection electrodes ELT are simultaneously formed, the number of masks may be reduced, the fabrication process may be simplified.

In an embodiment, as illustrated in FIG. 7, the connection electrodes ELT may be formed of conductive layers. The first connection electrode ETL1, the third connection electrode ELT3, and/or the fifth connection electrode ELT5 may be formed of a conductive layer. The second connection electrode ELT2 and the fourth connection electrode ELT4 may be formed of another conductive layer disposed on the first connection electrode ETL1, the third connection electrode ELT3, and/or the fifth connection electrode ELT5.

In this way, the light emitting elements LD aligned between the electrodes ALE may be connected in a desired form by using the connection electrodes ELT. For example, the first light emitting elements LD1, the second light emitting elements LD2, the third light emitting elements LD3, and the fourth light emitting elements LD4 may be successively connected in series by using the connection electrodes ELT.

Hereinafter, a cross-sectional structure of the pixel PXL will be described in more detail with reference to FIGS. 8 to 11. FIGS. 8 and 10 illustrate a first transistor M1 of various circuit elements that form the pixel circuit (refer to PXC of FIG. 5). In case that there is no need to separately designate the first to third transistors M1, M2, and M3, the term “transistor M” will be collectively used. The structures of the transistors M and/or positions in layers thereof are not limited to those of the embodiment shown in FIGS. 8 and 10 and may be changed in various ways depending on embodiments.

The pixels PXL in accordance with an embodiment may include circuit elements including transistors M disposed on the base layer BSL, and various lines connected to the circuit elements. The elements that form the above-stated emission component EMU may be disposed on the circuit elements.

The base layer BSL may form a base component and be formed of a rigid or flexible substrate or film. For example, the base layer BSL may be a rigid substrate made of glass or reinforced glass, a flexible substrate (or a thin film) formed of plastic or metal, or at least one insulating layer. The material and/or properties of the base layer BSL are not particularly limited. In an embodiment, the base layer BSL may be transparent. Here, the words “transparent” may mean that light can pass through the base layer BSL at a given transmissivity or more. In an embodiment, the base layer BSL may be translucent or opaque. Furthermore, the base layer BSL may include reflective material in an embodiment.

The bottom conductive layer BML and a first power conductive layer PL2a may be disposed on the base layer BSL. The bottom conductive layer BML and the first power conductive layer PL2a may be disposed on a same layer. For example, the bottom conductive layer BML and the first power conductive layer PL2a may be simultaneously formed through a same process, but the disclosure is not limited thereto. The first power conductive layer PL2a may form the second power line PL2 described with reference to FIG. 5 or the like within the spirit and the scope of the disclosure.

The bottom conductive layer BML and the first power conductive layer PL2a each may have a single layer structure or a multilayer structure that is formed of molybdenum (Mo), copper (Cu), aluminum (Al), chrome (Cr), gold (Au), titanium (Ti), nickel (Ni), neodymium (Nd), indium (In), tin (Sn), and an oxide or alloy thereof.

A buffer layer BFL may be disposed on the bottom conductive layer BML and the first power conductive layer PL2a. The buffer layer BFL may prevent impurities from diffusing into a circuit element. The buffer layer BFL may be formed of a single layer, or may be formed of multiple layers having at least two or more layers. In case that the buffer layer BFL has a multilayer structure, the respective layers may be formed of a same material or different materials.

A semiconductor pattern SCP may be disposed on the buffer layer BFL. For example, the semiconductor pattern SCP may include a first area which contacts a first transistor electrode TE1, a second area which contacts a second transistor electrode TE2, and a channel area disposed between the first and second areas. In an embodiment, one of the first and second areas may be a source area, and the other one may be a drain area.

In an embodiment, the semiconductor pattern SCP may be formed of polysilicon, amorphous silicon, an oxide semiconductor, or the like within the spirit and the scope of the disclosure. The channel area of the semiconductor pattern SCP may be an intrinsic semiconductor, which is an undoped semiconductor pattern. Each of the first and second areas of the semiconductor pattern SCP may be a semiconductor doped with a dopant.

A gate insulating layer GI may be disposed on the buffer layer BFL and the semiconductor pattern SCP. For example, the gate insulating layer GI may be disposed between the semiconductor pattern SCP and the gate electrode GE. Furthermore, the gate insulating layer GI may be disposed between the buffer layer BFL and a second power conductive layer PL2b. The gate insulating layer GI may be formed of a single layer or multiple layers, and include various inorganic materials including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

The gate electrode GE of the transistor M and the second power conductive layer PL2b may be disposed on the gate insulating layer GI. The gate electrode GE and the second power conductive layer PL2b may be disposed on a same layer. For example, the gate electrode GE and the second power conductive layer PL2b may be simultaneously formed through a same process, but the disclosure is not limited thereto. The gate electrode GE may be disposed on the gate insulating layer GI and overlap the semiconductor pattern SCP in the third direction DR3 (the Z-axis direction). The second power conductive layer PL2b may be disposed on the gate insulating layer GI and overlap the first power conductive layer PL2a in the third direction DR3 (the Z-axis direction). The second power conductive layer PL2b along with the first power conductive layer PL2a may form the second power line PL2 described with reference to FIG. 5 or the like within the spirit and the scope of the disclosure.

The gate electrode GE and the second power conductive layer PL2b each may have a single layer structure or a multilayer structure that is formed of molybdenum (Mo), copper (Cu), aluminum (Al), chrome (Cr), gold (Au), titanium (Ti), nickel (Ni), neodymium (Nd), indium (In), tin (Sn), and an oxide or alloy thereof. For example, the gate electrode GE and the second power conductive layer PL2b each may have a multilayer structure formed by successively or repeatedly stacking titanium (Ti), copper (Cu), and/or indium tin oxide (ITO) each other.

An interlayer insulating layer ILD may be disposed on the gate electrode GE and the second power conductive layer PL2b. For example, the interlayer insulating layer ILD may be disposed between the gate electrode GE and the first and second transistor electrodes TE1 and TE2. Furthermore, the interlayer insulating layer ILD may be disposed between the second power conductive layer PL2b and a third power conductive layer PL2c.

The interlayer insulating layer ILD may be formed of a single layer or multiple layers, and include various inorganic materials including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

The first and second transistor electrodes TE1 and TE2 of the transistor M and the third power conductive layer PL2c may be disposed on the interlayer insulating layer ILD. The first and second transistor electrodes TE1 and TE2 and the third power conductive layer PL2c may be disposed on a same layer. For example, the first and second transistor electrodes TE1 and TE2 and the third power conductive layer PL2c may be simultaneously formed through a same process, but the disclosure is not limited thereto.

The first and second transistor electrodes TE1 and TE2 may be disposed to overlap the semiconductor pattern SCP in the third direction DR3 (the Z-axis direction). The first and second transistor electrodes TE1 and TE2 may be electrically connected to the semiconductor pattern SCP. For example, the first transistor electrode TE1 may be electrically connected with the first area of the semiconductor pattern SCP through a contact hole passing through the interlayer insulating layer ILD. Furthermore, the first transistor electrode TE1 may be electrically connected with the bottom conductive layer BML through a contact hole passing through the interlayer insulating layer ILD and the buffer layer BFL. The second transistor electrode TE2 may be electrically connected with the second area of the semiconductor pattern SCP through a contact hole passing through the interlayer insulating layer ILD. In an embodiment, any one of the first and second transistor electrodes TE1 and TE2 may be a source electrode, and the other one may be a drain electrode.

The third power conductive layer PL2c may be disposed to overlap the first power conductive layer PL2a and/or the second power conductive layer PL2b in the third direction (the Z-axis direction). The third power conductive layer PL2c may be electrically connected to the first power conductive layer PL2a and/or the second power conductive layer PL2b. For example, the third power conductive layer PL2c may be electrically connected to the first power conductive layer PL2a through a contact hole passing through the interlayer insulating layer ILD and the buffer layer BFL. Furthermore, the third power conductive layer PL2c may be electrically connected to the second power conductive layer PL2b through a contact hole passing through the interlayer insulating layer ILD. The third power conductive layer PL2c along with the first power conductive layer PL2a and/or the second power conductive layer PL2b may form the second power line PL2 described with reference to FIG. 5 or the like within the spirit and the scope of the disclosure.

The first and second transistor electrodes TE1 and TE2 and the third power conductive layer PL2c each may have a single layer structure or a multilayer structure that is formed of molybdenum (Mo), copper (Cu), aluminum (Al), chrome (Cr), gold (Au), titanium (Ti), nickel (Ni), neodymium (Nd), indium (In), tin (Sn), and an oxide or alloy thereof.

A passivation layer PSV may be disposed on the first and second transistor electrodes TE1 and TE2 and the third power conductive layer PL2c. The passivation layer PSV may be formed of a single layer or multiple layers, and include various inorganic materials including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

A via layer VIA may be disposed on the passivation layer PSV. The via layer VIA may be formed of organic material for planarizing a stepped structure formed thereunder. For example, the via layer VIA may include organic material such as acrylic resin, epoxy resin, phenolic resin, polyamide resin, polyimide resin, polyester resin, polyphenylene sulfide resin, or benzocyclobutene (BCB). However, the disclosure is not limited thereto. The via layer VIA may include various inorganic materials including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ).

The partition walls WL may be disposed on the via layer VIA. The partition walls WL may function to form a given stepped structure to allow the light emitting elements LD to be readily aligned in the emission area EA.

Depending on embodiments, the partition walls WL may have various shapes. In an embodiment, the partition walls WL may have a shape protruding from the base layer BSL in the third direction (the Z-axis direction). Furthermore, the partition walls WL each may have an inclined surface which is inclined at a given angle with respect to the base layer BSL. However, the disclosure is not limited thereto. The partition walls WL each may have a sidewall having a curved or stepped shape. For example, the partition walls WL each may have a cross-sectional shape such as a semi-circular or semi-elliptical shape.

The partition walls WL each may include at least one organic material and/or inorganic material. For example, the partition walls WL each may include organic material such as acrylic resin, epoxy resin, phenolic resin, polyamide resin, polyimide resin, polyester resin, polyphenylene sulfide resin, or benzocyclobutene (BCB). However, the disclosure is not limited thereto. The partition walls WL each may include various inorganic materials including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

The electrodes ALE may be disposed on the via layer VIA and the partition walls WL. The electrodes ALE may at least partially cover sidewalls and/or upper surfaces of the partition walls WL. The electrodes ALE that are disposed over the partition walls WL may have shapes corresponding to the partition walls WL. For example, the electrodes ALE that are disposed on the partition walls WL may include inclined surfaces or curved surfaces having shapes corresponding to those of the partition walls WL. The partition walls WL and the electrodes ALE may function as reflectors, and reflect light emitted from the light emitting elements LD and guide the light in the frontal direction of the pixel PXL, for example, in the third direction (the Z-axis direction), whereby the light output efficiency of the display panel PNL may be enhanced.

The electrodes ALE may be disposed at positions spaced apart from each other. The electrodes ALE may be disposed on a same layer. For example, the electrodes ALE may be simultaneously formed through a same process, but the disclosure is not limited thereto.

The electrodes ALE may be supplied with alignment voltages at the step of aligning the light emitting elements LD. Therefore, an electric field may be formed between the electrodes ALE, so that the light emitting elements LD that are provided in each of the pixels PXL may be aligned between the electrodes ALE.

The electrodes ALE may include at least one conductive material. For example, the electrodes ALE may include at least one conductive material among at least one metal of various metal materials including silver (Ag), magnesium (Mg), aluminum (Al), platinum (Pt), palladium (Pd), gold (Au), nickel (Ni), neodymium (Nd), iridium (Ir), chrome (Cr), titanium (Ti), molybdenum (Mo), copper (Cu), etc., or an alloy thereof, conductive oxide such as indium tin oxide (ITO), indium zinc oxide (IZO), indium tin zinc oxide (ITZO), aluminum zinc oxide (AZO), gallium zinc oxide (GZO), zinc tin oxide (ZTO), or gallium tin oxide (GTO), and a conductive polymer such as PEDOT, but the disclosure is not limited thereto.

The first electrode ALE1 may be electrically connected to the first transistor electrode TE1 of the transistor M through a contact hole passing through the via layer VIA and the passivation layer PSV. The second electrode ALE2 may be electrically connected to the third power conductive layer PL2c through a contact hole passing through the via layer VIA and the passivation layer PSV.

A first insulating layer INS1 may be disposed on the electrodes ALE. The first insulating layer INS1 may be formed of a single layer or multiple layers, and include various inorganic materials including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

The first bank BNK1 may be disposed on the first insulating layer INS1. The first bank BNK1 may include an opening that overlaps the emission area EA. The opening of the first bank BNK1 may provide, at the step of supplying the light emitting elements LD to each pixel PXL, space to which the light emitting elements LD are to be provided. For example, a desired kind and/or amount of light emitting element ink may be supplied to the space defined by the opening of the first bank BNK1.

The first bank BNK1 may include organic material such as acrylic resin, epoxy resin, phenolic resin, polyamide resin, polyimide resin, polyester resin, polyphenylene sulfide resin, or benzocyclobutene (BCB). However, the disclosure is not limited thereto. The first bank BNK1 may include various inorganic materials including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

The light emitting elements LD may be disposed between the electrodes ALE. The light emitting elements LD may be provided in the opening of the first bank BNK1 and disposed between the partition walls WL.

The light emitting elements LD may be prepared in a diffused form in the light emitting element ink, and supplied to each of the pixels PXL by an inkjet printing scheme or the like within the spirit and the scope of the disclosure. For example, the light emitting elements LD may be diffused in a volatile solvent and supplied to each of the pixels PXL. Thereafter, if alignment voltages are supplied to the electrodes ALE, an electric field may be formed between the electrodes ALE so that the light emitting elements LD may be aligned between the electrodes ALE. After the light emitting elements LD have been aligned, the solvent may be removed by a volatilization scheme or other schemes. In this way, the light emitting elements LD may be reliably arranged between the electrodes ALE.

A second insulating layer INS2 may be disposed on the light emitting elements LD. For example, the second insulating layer INS2 may be partially provided on the light emitting elements LD so that the first and second ends EP1 and EP2 of the light emitting elements LD are exposed from the second insulating layer INS2. In case that the second insulating layer INS2 is formed on the light emitting elements LD after the alignment of the light emitting elements LD have been completed, the light emitting elements LD may be prevented from being removed from the aligned positions.

The second insulating layer INS2 may include organic material such as acrylic resin, epoxy resin, phenolic resin, polyamide resin, polyimide resin, polyester resin, polyphenylene sulfide resin, or benzocyclobutene (BCB). However, the disclosure is not limited thereto. The second insulating layer INS2 may include various inorganic materials including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

The connection electrodes ELT may be disposed on the first and second ends EP1 and EP2 of the light emitting elements LD that are exposed from the second insulating layer INS2.

The first connection electrode ELT1 may be disposed on or directly disposed on the first ends EP1 of the first light emitting elements LD1 and contact the first ends EP1 of the first light emitting elements LD1.

Furthermore, the second connection electrode ELT2 may be disposed on or directly disposed on the second ends EP2 of the first light emitting elements LD1 and contact the second ends EP2 of the first light emitting elements LD1. Furthermore, the second connection electrode ELT2 may be disposed on or directly disposed on the first ends EP1 of the second light emitting elements LD2 and contact the first ends EP1 of the second light emitting elements LD2. In other words, the second connection electrode ELT2 may electrically connect the second ends EP2 of the first light emitting elements LD1 with the first ends EP1 of the second light emitting elements LD2.

Likewise, the third connection electrode ELT3 may be disposed on or directly disposed on the second ends EP2 of the second light emitting elements LD2 and contact the second ends EP2 of the second light emitting elements LD2. Furthermore, the third connection electrode ELT3 may be disposed on or directly disposed on the first ends EP1 of the third light emitting elements LD3 and contact the first ends EP 1 of the third light emitting elements LD3. In other words, the third connection electrode ELT3 may electrically connect the second ends EP2 of the second light emitting elements LD2 with the first ends EP1 of the third light emitting elements LD3.

Likewise, the fourth connection electrode ELT4 may be disposed on or directly disposed on the second ends EP2 of the third light emitting elements LD3 and contact the second ends EP2 of the third light emitting elements LD3. Furthermore, the fourth connection electrode ELT4 may be disposed on or directly disposed on the first ends EP1 of the fourth light emitting elements LD4 and contact the first ends EP1 of the fourth light emitting elements LD4. In other words, the fourth connection electrode ELT4 may electrically connect the second ends EP2 of the third light emitting elements LD3 with the first ends EP1 of the fourth light emitting elements LD4.

Likewise, the fifth connection electrode ELT5 may be disposed on or directly disposed on the second ends EP2 of the fourth light emitting elements LD4 and contact the second ends EP2 of the fourth light emitting elements LD4.

The first connection electrode ELT1 may be electrically connected to the first electrode ALE1 through the corresponding contact hole passing through the first insulating layer INS1. The fifth connection electrode ELT5 may be electrically connected to the second electrode ALE2 through the corresponding contact hole passing through the first insulating layer INS1.

In an embodiment, the connection electrodes ELT may be formed of an identical conductive layer. For example, as illustrated in FIGS. 8 and 9, the first to fifth connection electrodes ELT1, ELT2, ELT3, ELT4, and ELT5 may be formed of a same conductive layer. For instance, the first to fifth connection electrodes ELT1, ELT2, ELT3, ELT4, and ELT5 may be simultaneously formed through a same process. As such, in case that the connection electrodes ELT are simultaneously formed, the number of masks may be reduced, the fabrication process may be simplified.

In an embodiment, the connection electrodes ELT may be formed of conductive layers. For example, as illustrated in FIGS. 10 and 11, the first connection electrode ELT1, the third connection electrode ELT3, and the fifth connection electrode ELT5 may be disposed on a same layer. Furthermore, the second connection electrode ELT2 and the fourth connection electrode ELT4 may be disposed on a same layer. The first connection electrode ELT1, the third connection electrode ELT3, and the fifth connection electrode ELT5 may be disposed on the second insulating layer INS2. A third insulating layer INS3 may be disposed on the first connection electrode ELT1, the third connection electrode ELT3, and the fifth connection electrode ELT5. The second connection electrode ELT2 and the fourth connection electrode ELT4 may be disposed on the third insulating layer INS3.

As such, in case that the third insulating layer INS3 is disposed between the connection electrodes ELT that are formed of different conductive layers, the connection electrodes ELT may be reliably separated from each other by the third insulating layer INS3, so that electrical stability between the first and second ends EP1 and EP2 of the light emitting elements LD can be secured.

The third insulating layer INS3 may be formed of a single layer or multiple layers, and include various inorganic materials including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

The connection electrodes ELT each may be formed of various transparent conductive materials. Hence, light emitted from the first and second ends EP1 and EP2 of the light emitting elements LD may pass through the connection electrodes ELT and be emitted outside the display panel PNL.

FIG. 12 is a schematic plan view illustrating a dummy pixel DP in accordance with an embodiment. FIG. 13 is a schematic cross-sectional view taken along line E-E′ of FIG. 12.

Referring to FIGS. 12 and 13, the dummy pixel DP may be any one of the first dummy pixel DP1 and the second dummy pixel DP2 of FIGS. 3 and 4. The first dummy pixel DP1 and the second dummy pixel DP2 may have identical or similar structures.

The dummy pixel DP may include dummy partition walls DWL and the dummy electrodes DALE.

The dummy partition walls DWL may extend in the second direction (the Y-axis direction) and be spaced apart from each other in the first direction (the X-axis direction). The dummy partition walls DWL may have shapes identical to those of the above-stated partition walls WL. The dummy partition walls DWL may be disposed on the above-stated via layer VIA. The dummy partition walls DWL may be disposed on a same layer as that of the partition walls WL.

The dummy partition walls DWL may include at least one organic material and/or inorganic material. For example, the dummy partition walls DWL each may include organic material such as acrylic resin, epoxy resin, phenolic resin, polyamide resin, polyimide resin, polyester resin, polyphenylene sulfide resin, or benzocyclobutene (BCB). However, the disclosure is not limited thereto. The dummy partition wall DWL may include various inorganic materials including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ). The dummy partition walls DWL may include material identical to that of the above-stated partition walls WL. For example, the dummy partition walls DWL and the partition walls WL may be simultaneously formed through a same process, but the disclosure is not limited thereto.

The dummy electrodes DALE may extend in the second direction (the Y-axis direction) and be spaced apart from each other in the first direction (the X-axis direction). The dummy electrodes DALE each may partially overlap at least one of the dummy partition walls DWL. For example, the dummy electrodes DALE may be disposed on the dummy partition walls DWL. The dummy electrodes DALE may at least partially cover sidewalls and/or upper surfaces of the dummy partition walls DWL. The dummy electrodes DALE that are disposed over the dummy partition walls DWL may have shapes corresponding to the dummy partition walls DWL. For example, the dummy electrodes DALE that are disposed on the dummy partition walls DWL may include inclined surfaces or curved surfaces having shapes corresponding to those of the dummy partition walls DWL. The dummy electrodes DALE may have shapes identical to as those of the above-stated electrodes ALE. The dummy electrodes DALE may be disposed on a same layer as that of the electrodes ALE.

The dummy electrodes DALE may include at least one conductive material. For example, the dummy electrodes DALE may include at least one material among at least one metal of various metal materials including silver (Ag), magnesium (Mg), aluminum (Al), platinum (Pt), palladium (Pd), gold (Au), nickel (Ni), neodymium (Nd), iridium (Ir), chrome (Cr), titanium (Ti), molybdenum (Mo), copper (Cu), etc., or an alloy thereof, conductive oxide such as indium tin oxide (ITO), indium zinc oxide (IZO), indium tin zinc oxide (ITZO), aluminum zinc oxide (AZO), gallium zinc oxide (GZO), zinc tin oxide (ZTO), or gallium tin oxide (GTO), and a conductive polymer such as PEDOT, but the disclosure is not limited thereto. The dummy electrodes DALE may have material identical to that of the above-stated electrodes ALE. For example, the dummy electrodes DALE and the electrodes ALE may be simultaneously formed through a same process, but the disclosure is not limited thereto. As such, since the dummy pixels DP include the dummy partition walls DWL and/or the dummy electrodes DALE identical or similar to the partition walls WL and/or the electrodes ALE of the pixels PXL, a phenomenon in which a spot defect occurs in the display area DA due to a difference in density between the partition walls and/or the electrodes may be minimized.

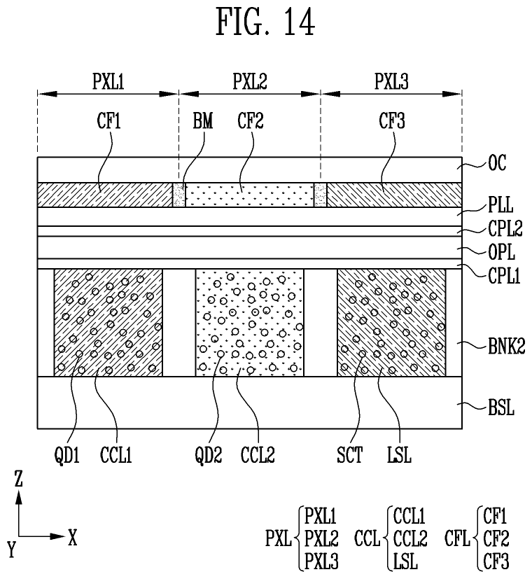

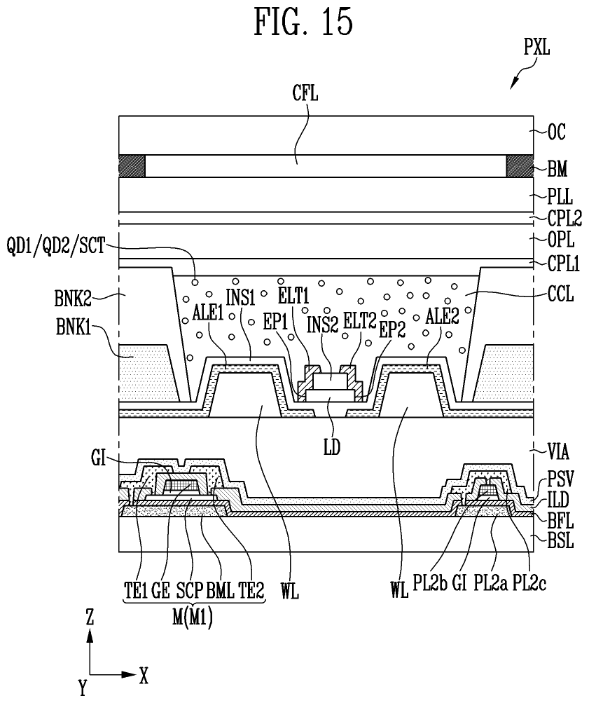

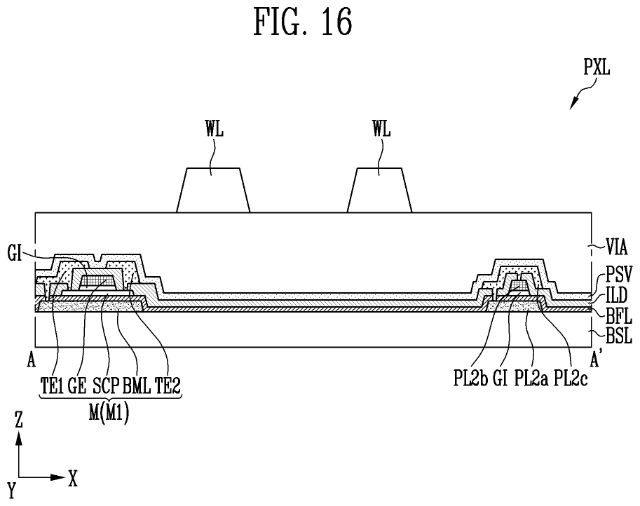

FIG. 14 is a schematic cross-sectional view illustrating first to third pixels PXL1, PXL2, and PXL3 in accordance with an embodiment. FIG. 15 is a schematic cross-sectional view illustrating a pixel PXL in accordance with an embodiment.

FIG. 14 illustrates a second bank BNK2, a color conversion layer CCL, an optical layer OPL, a color filter layer CFL, and/or the like within the spirit and the scope of the disclosure. In FIG. 14, for the sake of convenience, configurations other than the base layer BSL will be omitted. FIG. 15 illustrates in detail a stacked structure of the pixel PXL with regard to the second bank BNK2, the color conversion layer CCL, the optical layer OPL, and/or the color filter layer CFL.

Referring to FIGS. 14 and 15, the second bank BNK2 may be disposed between the first to third pixels PXL1, PXL2, and PXL3 or on boundaries therebetween, and include openings which respectively overlap the first to third pixels PXL1, PXL2, and PXL3. The openings of the second bank BNK2 may provide space in which the color conversion layer CCL can be provided. For example, a desired kind and/or amount of color conversion layer CCL may be supplied to the space defined by each of the openings of the second bank BNK2.

The second bank BNK2 may include organic material such as acrylic resin, epoxy resin, phenolic resin, polyamide resin, polyimide resin, polyester resin, polyphenylene sulfide resin, or benzocyclobutene (BCB). However, the disclosure is not limited thereto. The second bank BNK2 may include various inorganic materials including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

In an embodiment, the second bank BNK2 may include at least one light shielding and/or reflective material. Therefore, a light leakage between adjacent pixels PXL may be prevented from being caused. For example, the second bank BNK2 may include a black pigment, but the disclosure is not limited thereto.

The color conversion layer CCL may be disposed on the light emitting elements LD in the openings of the second bank BNK2. The color conversion layer CCL may include a first color conversion layer CCL1 disposed in the first pixel PXL1, a second color conversion layer CCL2 disposed in the second pixel PXL2, and a light scattering layer LSL disposed in the third pixel PXL3.

In an embodiment, the first, second, and third pixels PXL1, PXL2, and PXL3 may include light emitting elements LD that emit a same color of light. In an embodiment, the first to third pixels PXL1, PXL2, and PXL3 may include light emitting elements LD that emit the third color of light (or blue light). Since the color conversion layer CCL including color conversion particles is disposed in each of the first to third pixels PXL1, PXL2, and PXL3, a full-color image may be displayed.

The first color conversion layer CCL1 may include first color conversion particles for converting the third color of light emitted from the light emitting element LD to the first color of light. For example, the first color conversion layer CCL1 may include first quantum dots QD1 which are dispersed in a matrix material such as base resin.

In an embodiment, in case that the light emitting element LD is a blue light emitting element that emits blue light and the first pixel PXL1 is a red pixel, the first color conversion layer CCL1 may include the first quantum dots QD1 which convert blue light emitted from the blue light emitting element to red light. The first quantum dots QD1 may absorb blue light, shift the wavelength thereof according to an energy transition, and thus emit red light. In case that the first color pixel PXL1 is a pixel of a different color, the first color conversion layer CCL1 may include the first quantum dots QD1 corresponding to the color of the first pixel PXL1.

The second color conversion layer CCL2 may include second color conversion particles for converting the third color of light emitted from the light emitting element LD to the second color of light. For example, the second color conversion layer CCL2 may include second quantum dots QD2 which are dispersed in a matrix material such as base resin.

In an embodiment, in case that the light emitting element LD is a blue light emitting element that emits blue light and the second pixel PXL2 is a green pixel, the second color conversion layer CCL2 may include the second quantum dots QD2 which convert blue light emitted from the blue light emitting element to green light. The second quantum dots QD2 may absorb blue light, shift the wavelength thereof according to an energy transition, and thus emit green light. In case that the second color pixel PXL2 is a pixel of a different color, the second color conversion layer CCL2 may include the second quantum dots QD2 corresponding to the color of the second pixel PXL2.

In an embodiment, as blue light having a relatively short wavelength in a visible ray area is incident on each of the first quantum dots QD1 and the second quantum dots QD2, absorption coefficients of the first quantum dot QD1 and the second quantum dot QD2 may be increased. Therefore, eventually, the efficiency of light emitted from the first pixel PXL1 and the second pixel PXL2 may be enhanced, and satisfactory color reproducibility may be secured. Furthermore, since emission circuits EMU for the first to third pixels PXL1, PXL2, and PXL3 are formed of light emitting elements LD (for example, blue light emitting elements) that emit a same color of light, the efficiency of the process of fabricating the display device may be enhanced.

The light scattering layer LSL may be provided to efficiently use the third color of light (or blue light) emitted from the light emitting element LD. For example, in case that the light emitting element LD is a blue light emitting element that emits blue light and the third pixel PXL3 is a blue pixel, the light scattering layer LSL may include at least one type of light scatterers SCT to efficiently use light emitted from the light emitting element LD. For example, the light scatterers SCT of the light scattering layer LSL may include at least one of barium sulfate (BaSO₄), calcium carbonate (CaCO₃), titanium oxide (TiO₂), silicon oxide (SiO₂), aluminum oxide (Al₂O₃), and zinc oxide (ZnO). The light scatterers SCT may not only be provided in the third pixel PXL3, but may also be selectively included in the first conversion layer CCL1 or the second color conversion layer CCL2. In an embodiment, the light scatterers SCT may be omitted, and the light scattering layer LSL may be formed of transparent polymer.

A first capping layer CPL1 may be disposed on the color conversion layer CCL. The first capping layer CPL1 may be provided over the first to third pixels PXL1, PXL2, and PXL3. The first capping layer CPL1 may cover the color conversion layer CCL. The first capping layer CPL1 may prevent the color conversion layer CCL from being damaged or contaminated by permeation of external impurities such as water or air.

The first capping layer CPL1 may be an inorganic layer, and be formed of silicon nitride (SiNₓ), aluminum nitride (AlNₓ), titanium nitride (TiNₓ), silicon oxide (SiOₓ), aluminum oxide (AlOₓ), titanium oxide (TiOₓ), silicon oxycarbide (SiOₓC_{y}), or silicon oxynitride (SiOₓN_{y}).

The optical layer OPL may be disposed on the first capping layer CPL1. The optical layer OPL may function to recycle light provided from the color conversion layer CCL by total reflection and thus enhance light extraction efficiency. Hence, the optical layer OPL may have a relatively low refractive index compared to that of the color conversion layer CCL. For example, the refractive index of the color conversion layer CCL may approximately range from 1.6 to 2.0, and the refractive index of the optical layer OPL may approximately range from 1.1 to 1.3.

A second capping layer CPL2 may be disposed on the optical layer OPL. The second capping layer CPL2 may be provided over the first to third pixels PXL1, PXL2, and PXL3. The second capping layer CPL2 may cover the optical layer OPL. The second capping layer CPL2 may prevent the optical layer OPL from being damaged or contaminated by permeation of external impurities such as water or air.

The second capping layer CPL2 may be an inorganic layer, and be formed of silicon nitride (SiNₓ), aluminum nitride (AlNₓ), titanium nitride (TiNₓ), silicon oxide (SiOₓ), aluminum oxide (AlOₓ), titanium oxide (TiOₓ), silicon oxycarbide (SiOₓC_{y}), or silicon oxynitride (SiOₓN_{y}).

A planarization layer PLL may be disposed on the second capping layer CPL2. The planarization layer PLL may be provided over the first to third pixels PXL1, PXL2, and PXL3.

The planarization layer PLL may include organic material such as acrylic resin, epoxy resin, phenolic resin, polyamide resin, polyimide resin, polyester resin, polyphenylene sulfide resin, or benzocyclobutene (BCB). However, the disclosure is not limited thereto. The planarization layer PLL may include various inorganic materials including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

The color filter layer CFL may be disposed on the planarization layer PLL. The color filter layer CFL may include color filters CF1, CF2, and CF3 corresponding to the colors of the respective pixels PXL. Since the color filters CF1, CF2, and CF3 corresponding to the respective colors of the first to third pixels PXL1, PXL2, and PXL3 are disposed, a full-color image may be displayed.

The color filter layer CFL may include a first color filter CF1 disposed in the first pixel PXL1 and allows light emitted from the first pixel PXL1 to selectively pass therethrough, a second color filter CF2 disposed in the second pixel PXL2 and allows light emitted from the second pixel PXL2 to selectively pass therethrough, and a third color filter CF3 disposed in the third pixel PXL3 and allows light emitted from the third pixel PXL3 to selectively pass therethrough.

In an embodiment, the first color filter CF1, the second color filter CF2, and the third color filter CF3 may be respectively a red color filter, a green color filter, and a blue color filter, but the disclosure is not limited thereto. Hereinafter, the term “color filter CF” or “color filters CF” will be used to designate any color filter among the first color filter CF1, the second color filter CF2, and the third color filter CF3, or collectively designate two or more kinds of color filters.

The first color filter CF1 may overlap the first color conversion layer CCL1 in the third direction (the Z-axis direction). The first color filter CF1 may include color filter material for allowing the first color of light (or red light) to selectively pass therethrough. For example, in case that the first pixel PXL1 is a red pixel, the first color filter CF1 may include red color filter material.

The second color filter CF2 may overlap the second color conversion layer CCL2 in the third direction (the Z-axis direction). The second color filter CF2 may include color filter material for allowing the second color of light (or green light) to selectively pass therethrough. For example, in case that the second pixel PXL2 is a green pixel, the second color filter CF2 may include green color filter material.

The third color filter CF3 may overlap the light scattering layer LSL in the third direction (the Z-axis direction). The third color filter CF3 may include color filter material for allowing the third color of light (or blue light) to selectively pass therethrough. For example, in case that the third pixel PXL3 is a blue pixel, the third color filter CF3 may include blue color filter material.

In an embodiment, a light shielding layer BM may be further disposed between the first to third color filters CF1, CF2, and CF3. In case that the light shielding layer BM is formed between the first to third color filters CF1, CF2, and CF3, a color mixing defect which is visible from a front surface or side surface of the display device may be prevented from occurring. The material of the light shielding layer BM is not particularly limited, and various light shielding materials may be used to form the light shielding layer BM. For example, the light shielding layer BM may be embodied by stacking the first to third color filters CF1, CF2, and CF3 each other.

An overcoat layer OC may be disposed on the color filter layer CFL. The overcoat layer OC may be provided over the first to third pixels PXL1, PXL2, and PXL3. The overcoat layer OC may cover a lower component including the color filter layer CFL. The overcoat layer OC may prevent water or air from permeating the lower component. Furthermore, the overcoat layer OC may protect the lower component from foreign material such as dust.

The overcoat layer OC may include organic material such as acrylic resin, epoxy resin, phenolic resin, polyamide resin, polyimide resin, polyester resin, polyphenylene sulfide resin, or benzocyclobutene (BCB). However, the disclosure is not limited thereto. The overcoat layer OC may include various inorganic materials including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

Hereinafter, a method of fabricating the display device in accordance with an embodiment will be described.

FIGS. 16 to 23 are schematic cross-sectional views illustrating, by process steps, a method of fabricating the display device in accordance with an embodiment. FIGS. 16 to 23 are schematic cross-sectional views for describing the method of fabricating the display device of FIGS. 8 and 11. Like references will be used to designate substantially the same components as those of the embodiment of FIGS. 8 and 11, and detailed explanation thereof will be omitted.

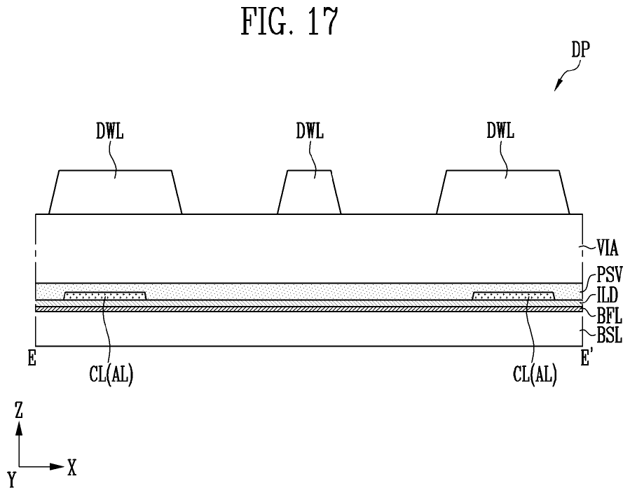

Referring to FIGS. 16 and 17, the partition walls WL and the dummy partition walls DWL are first formed on the base layer BSL on which circuit elements including the transistor M, and various lines including the conductive lines CL and the alignment lines AL are formed.

The base layer BSL may form the base component of the mother substrate MSUB that has been described with reference to FIG. 4. The mother substrate MSUB may be a mother board that is the base of the display panel PNL. For example, the transistor M and the conductive lines CL may be formed in the panel area PNA of the base layer BSL of the mother substrate MSUB, and the alignment lines AL may be formed in the cutting area CA.

The partition walls WL may be formed in the pixel PXL, and the dummy partition walls DWL may be formed in the dummy pixel DP. For example, the dummy partition walls DWL may be respectively formed in the first dummy pixel DP1 disposed in the panel area PNA of the mother substrate MSUB, and the second dummy pixel DP2 disposed in the cutting area CA of the mother substrate MSUB. The partition walls WL and the dummy partition walls DWL may be simultaneously formed through a same process.

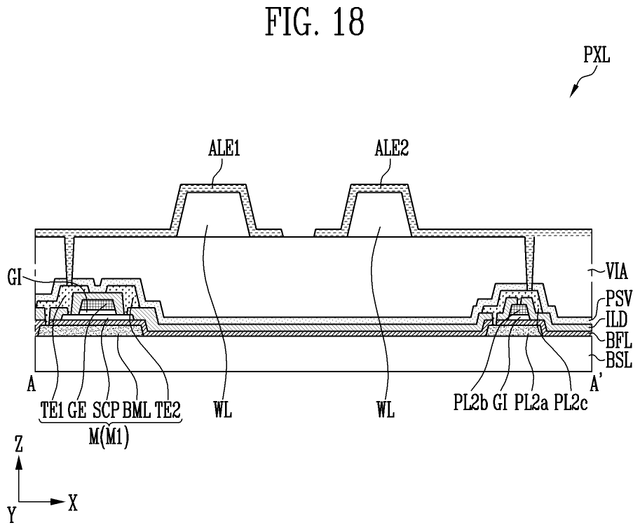

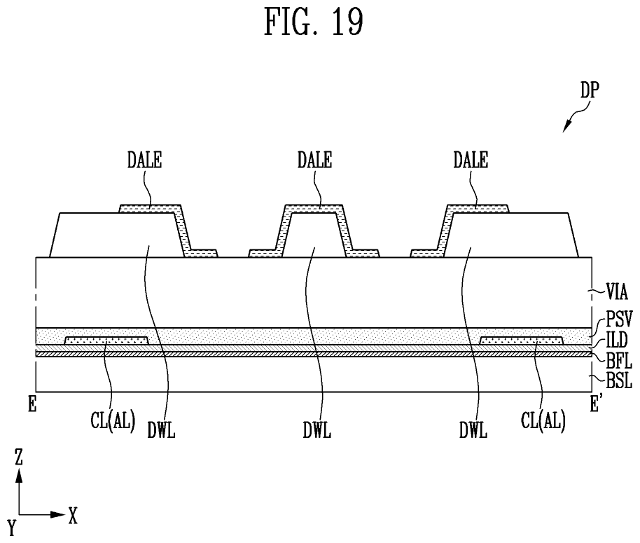

Referring to FIGS. 18 and 19, the electrodes ALE and the dummy electrodes DALE are thereafter formed. The electrodes ALE may be formed in the pixel PXL. The electrodes ALE may be formed on the partition walls WL and overlap the partition walls WL.

The dummy electrodes DALE may be formed in the dummy pixel DP. The dummy electrode DALE may be formed on the dummy partition wall DWL and overlap the dummy partition wall DWL. The electrodes ALE and the dummy electrodes DALE may be simultaneously formed through a same process.

The dummy electrodes DALE may be respectively formed in the first dummy pixel DP1 disposed in the panel area PNA of the mother substrate MSUB, and the second dummy pixel DP2 disposed in the cutting area CA of the mother substrate MSUB. The dummy electrodes DALE formed in the first dummy pixel DP1 may be formed on the above-stated conductive lines CL and overlap the conductive lines CL. Furthermore, the dummy electrodes DALE formed in the second dummy pixel DP2 may be formed on the above-stated alignment lines AL and overlap the alignment lines AL.

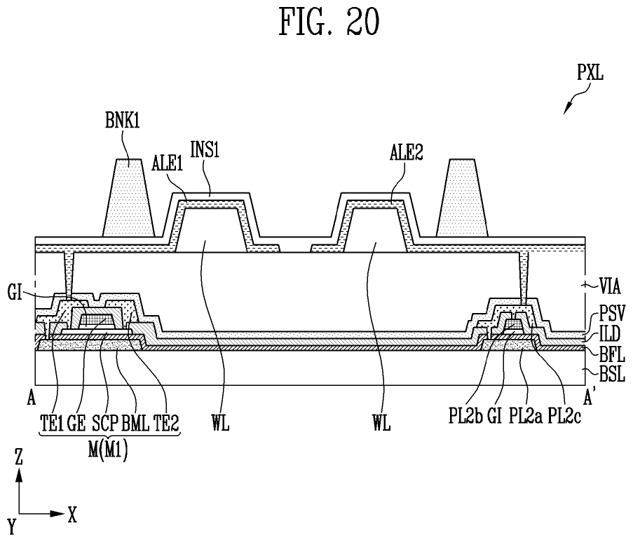

Referring to FIG. 20, the first insulating layer INS1 and the first bank BNK1 are thereafter formed on the electrodes ALE. The first bank BNK1 may define space to which the light emitting elements LD can be provided, at the step of supplying the light emitting elements LD to the pixel PXL. For example, a desired kind and/or amount of light emitting element ink may be supplied to the space defined by the opening of the first bank BNK1.

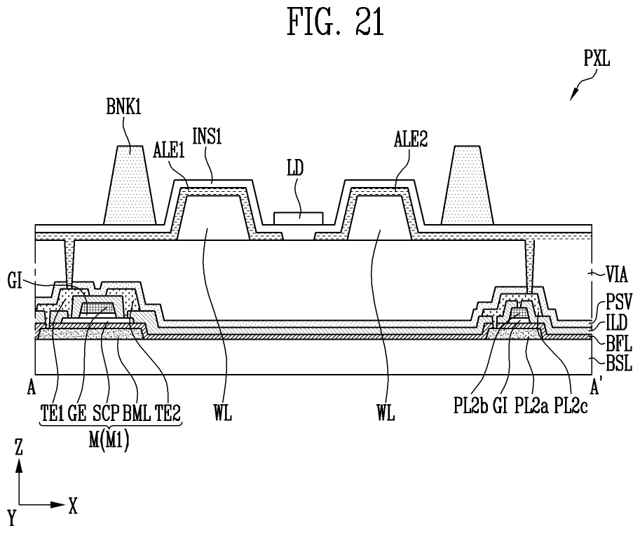

Referring to FIG. 21, the light emitting elements LD are thereafter provided between the electrodes ALE. The light emitting elements LD may be provided on the first insulating layer INS1 between the partition walls WL and arranged between the electrodes ALE. The light emitting elements LD may be prepared in a diffused form in the light emitting element ink, and supplied to the pixel PXL by an inkjet printing scheme or the like within the spirit and the scope of the disclosure. For example, the light emitting elements LD may be diffused in a volatile solvent and provided to the pixel PXL. Thereafter, if alignment voltages are supplied to the electrodes ALE through the alignment lines AL, an electric field may be formed between the electrodes ALE so that the light emitting elements LD may be aligned between the electrodes ALE. For example, the light emitting elements LD may be aligned in a given direction between the electrodes ALE such that the first ends EP1 of the light emitting elements LD are adjacent to the first electrode ALE1, and the second ends EP2 of the light emitting elements LD are adjacent to the second electrode ALE2. After the light emitting elements LD have been aligned, the solvent may be removed by a volatilization scheme or other schemes. In this way, the light emitting elements LD may be reliably arranged between the electrodes ALE.

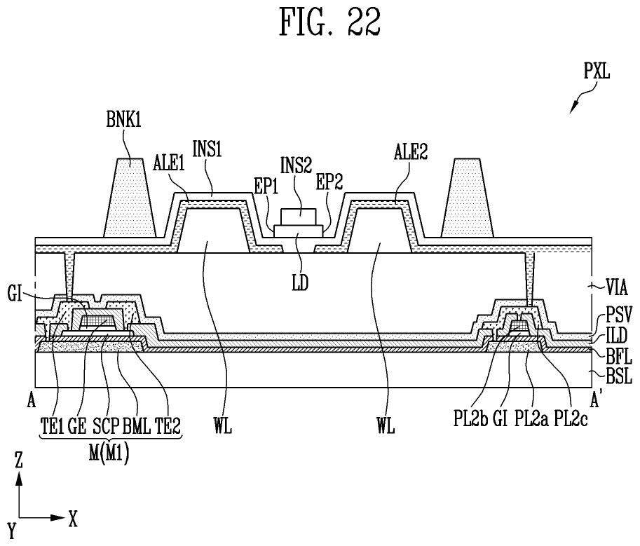

Referring to FIG. 22, the second insulating layer INS2 is thereafter formed on the light emitting elements LD. The second insulating layer INS2 may be partially formed over the light emitting elements LD so that the first and second ends EP1 and EP2 of the light emitting elements LD are exposed from the second insulating layer INS2. In case that the second insulating layer INS2 is formed on the light emitting elements LD after the alignment of the light emitting elements LD have been completed, the light emitting elements LD may be prevented from being removed from the aligned positions.

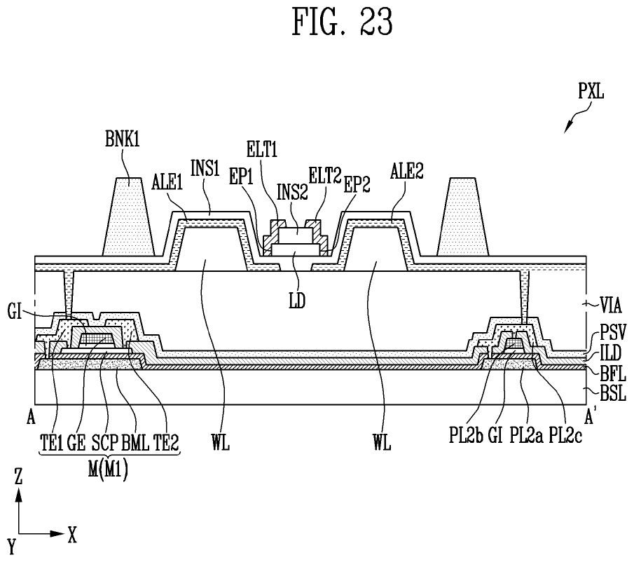

Referring to FIG. 23, the connection electrodes ELT are thereafter formed on the first and second ends EP1 and EP2 of the light emitting elements LD that are exposed from the second insulating layer INS2. The first connection electrode ELT1 may be formed on the first ends EP1 of the light emitting elements LD and contact the first ends EP1 of the light emitting elements LD. The second connection electrode ELT2 may be formed on the second ends EP2 of the light emitting elements LD and contact the second ends EP2 of the light emitting elements LD.

Subsequently, the cutting area CA of the mother substrate MSUB is cut, so that the display panel PNL corresponding to the panel area PNA can be manufactured.

In accordance with the above-described embodiment, since the dummy partition walls DWL and/or the dummy electrodes DALE identical or similar to the partition walls WL and/or the electrodes ALE of the pixels PXL are formed in the panel area PNA and the cutting area CA of the mother substrate MSUB, a phenomenon in which a spot defect occurs in the display area DA due to a difference in density between the partition walls and/or the electrodes may be minimized.

It will be understood by those skilled in the art that various changes in form and details may be made therein without departing from the spirit and scope of the disclosure and as defined by the appended claims. Therefore, the foregoing embodiments should be considered in a descriptive sense only and not for purposes of limitation. The scope of the disclosure is defined not only by the detailed description but by the appended claims, and all differences within the scope will be construed as being included in the disclosure.

What is claimed is:

1. A display device comprising:
electrodes disposed in a display area and spaced apart from each other;
light emitting elements disposed between the electrodes;
conductive lines disposed in a non-display area and electrically connected to the electrodes; and
dummy pixels disposed on the conductive lines, wherein
the dummy pixels each comprise:
dummy partition walls spaced apart from each other; and
dummy electrodes disposed on the partition walls and spaced apart from each other.

2. The display device according to claim 1, wherein the electrodes and the dummy electrodes are disposed on a same layer.

3. The display device according to claim 1, wherein the electrodes comprise a first electrode adjacent to first ends of the light emitting elements, and a second electrode adjacent to second ends of the light emitting elements.

4. The display device according to claim 3, wherein the conductive lines comprise a first conductive line electrically connected to the first electrode, and a second conductive line electrically connected to the second electrode.

5. The display device according to claim 1, further comprising:
partition walls overlapping the electrodes in a plan view.

6. The display device according to claim 5, wherein the partition walls and the dummy partition walls are disposed on a same layer.

7. A method of fabricating a display device, comprising:
forming alignment lines on a substrate;
forming dummy electrodes on the alignment lines;
forming electrodes connected with the alignment lines;
providing light emitting elements on the substrate; and
aligning the light emitting elements between the electrodes by applying alignment voltages to the alignment lines.

8. The method according to claim 7, wherein the electrodes and the dummy electrodes are simultaneously formed.

9. The method according to claim 7, further comprising:
forming dummy partition walls between the alignment lines and the dummy electrodes.

10. The method according to claim 9, further comprising:
forming partition walls overlapping the electrodes in a plan view.

11. The method according to claim 10, wherein the partition walls and the dummy partition walls are simultaneously formed.

12. The method according to claim 7, wherein the alignment lines are formed in a cutting area of the substrate.

13. The method according to claim 12, wherein the dummy electrodes are formed in the cutting area of the substrate.

14. The method according to claim 12, wherein the electrodes are formed in a panel area of the substrate.

15. The method according to claim 14, further comprising:
forming conductive lines in the panel area of the substrate, the conductive lines connecting the alignment lines and the electrodes to each other.

16. The method according to claim 12, further comprising:
forming a display panel by cutting the cutting area of the substrate.

17. The method according to claim 7, wherein the electrodes comprise a first electrode adjacent to first ends of the light emitting elements, and a second electrode adjacent to second ends of the light emitting elements.

18. The method according to claim 17, wherein the alignment lines comprise a first alignment line connected to the first electrode, and a second alignment line connected to the second electrode.

19. The method according to claim 18, wherein the applying of the alignment voltages to the alignment lines comprises applying a first alignment voltage to the first alignment line, and applying a second alignment voltage to the second alignment line.

20. The method according to claim 19, wherein the first alignment voltage comprises a ground voltage, and the second alignment voltage comprises an alternating current voltage.
